(19) United States
(12) Patent Application Publication
(10) Pub. No.: US 2025/0336455 A1
(43) Pub. Date: Oct. 30, 2025

(54) MEMORY DEVICE, OPERATING METHOD OF MEMORY DEVICE, AND STORAGE DEVICE INCLUDING MEMORY DEVICE

(71) Applicant: Samsung Electronics Co., Ltd., Suwon-si (KR)

(72) Inventors: LAESANG JUNG, Suwon-si (KR); SANG-IN PARK, Suwon-si (KR)

(21) Appl. No.: 19/078,252

(22) Filed: Mar. 12, 2025

(30) Foreign Application Priority Data
Apr. 24, 2024 (KR) 10-2024-0054701

(51) Int. Cl. G11C 16/34; G11C 16/10; G11C 29/52

(52) U.S. Cl. CPC G11C 16/3459; G11C 16/102; G11C 29/52

(57) ABSTRACT

A memory device includes a memory cell array that includes a plurality of memory cells, a page buffer that temporarily stores data, which are received from an external controller and are to be stored in the memory cell array, and an error data detector that generates a bit count by counting the number of bits each having a first bit value from among a plurality of bits included in first data, which are temporarily stored in the page buffer and are to be stored in the memory cell array, and determines whether the first data are error data, based on the bit count.

### CROSS-REFERENCE TO RELATED APPLICATION(S)

This application claims priority under 35 U.S.C. § 119 to Korean Patent Application No. 10-2024-0054701 filed on Apr. 24, 2024, in the Korean Intellectual Property Office, the disclosure of which is incorporated by reference herein in its entirety.

### BACKGROUND

Embodiments of the present disclosure described herein relate to a semiconductor memory device, and more particularly, relate to a memory device, an operating method of the memory device, and a storage device including the memory device.

A semiconductor memory is classified as a volatile memory, which loses data stored therein when a power is turned off, such as a static random access memory (SRAM), a dynamic RAM (DRAM), or a synchronous DRAM (SDRAM) and a nonvolatile memory, which retains data stored therein even when a power is turned off, such as a read only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a resistive RAM (RRAM), or a ferroelectric RAM (FRAM).

The flash memory is being widely used as a high-capacity storage medium of a user device. With development of computing technologies, nowadays, a flash memory-based high-capacity storage medium is requiring more improved performance. Various techniques or devices are being developed to improve the performance of the flash memory-based high-capacity storage medium. However, defects in memory devices may increase as the speed of memory devices increases. Therefore, improved testing for defects may be useful for improving the performance of memory devices.

### SUMMARY

Embodiments of the present disclosure provide a memory device with improved performance, an operating method of the memory device, and a storage device including the memory device.

According to an embodiment, a memory device includes a memory cell array that includes a plurality of memory cells, a page buffer that temporarily stores data, which are received from an external controller and are to be stored in the memory cell array, and an error data detector that generates a bit count by counting the number of bits each having a first bit value from among a plurality of bits included in first data, which are temporarily stored in the page buffer and are to be stored in the memory cell array, and determines whether the first data are error data, based on the bit count.

According to an embodiment, an operating method of a memory device which includes a memory cell array and a page buffer includes receiving program data from an external controller, storing the program data in the page buffer, generating a bit count by counting the number of bits each having a first bit value from among a plurality of bits included in the program data temporarily stored in the page buffer, and determining whether the program data are error data, based on the bit count.

According to an embodiment, a storage device includes a memory device that stores data, and a memory controller that sends program data to the memory device. The memory device includes a memory cell array that includes memory cells connected to word lines, a row decoder that drives the word lines, a page buffer that temporarily stores the program data, and a control logic circuit that includes an error data detector which determines whether the program data stored in the page buffer are error data. During a program execution time, the error data detector generates a bit count by counting the number of bits each having a first bit value from among a plurality of bits included in the program data and determines whether the program data are the error data, based on the bit count. The memory device may be configured to store the program data in the memory cell array during the program execution time.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a storage device according to an embodiment of the present disclosure.

FIG. 2 is a block diagram illustrating a memory controller of FIG. 1 according to example embodiments.

FIG. 3 is a block diagram illustrating a memory device of FIG. 1 according to example embodiments.

FIG. 4 is a circuit diagram illustrating a memory block of FIG. 3 according to example embodiments.

FIGS. 5A and 5B are diagrams illustrating threshold voltage distributions of memory cells illustrated in FIG. 4 according to example embodiments.

FIG. 6 is a block diagram illustrating a page buffer of FIG. 3 according to example embodiments.

FIG. 7 is a diagram for describing an example of an operation of a memory device of FIG. 3 according to example embodiments.

FIG. 8 is a flowchart for describing an operating method of a memory device of FIG. 3 according to example embodiments.

FIG. 9 is a diagram for describing an operation of determining whether program data are error data, which is described with reference to FIG. 8, in detail, according to example embodiments.

FIGS. 10 to 12 are diagrams for describing an operation of generating a bit count, which is described with reference to FIG. 8 according to example embodiments.

FIG. 13 is a graph for describing reference values of FIG. 10 according to example embodiments.

FIGS. 14A to 14C are diagrams for describing a timing at which error data detection is performed, according to example embodiments.

FIGS. 15A to 15C are diagrams for describing a timing at which error data detection is performed, according to example embodiments.

FIGS. 16A to 16C are flowcharts for describing an operating method of a storage device of FIG. 1 according to example embodiments.

FIG. 17 is a flowchart for describing an operation of a memory device of FIG. 3 according to example embodiments.

FIG. 18 is a block diagram illustrating a memory system according to an embodiment of the present disclosure.

### DETAILED DESCRIPTION

Below, embodiments of the present disclosure will be described in detail and clearly to such an extent that one skilled in the art easily carries out the present disclosure.

In the specification, function blocks of drawings, which respectively correspond to the terms “block”, “unit”, “logic”, etc., may be implemented in the form of software, hardware, or a combination thereof.

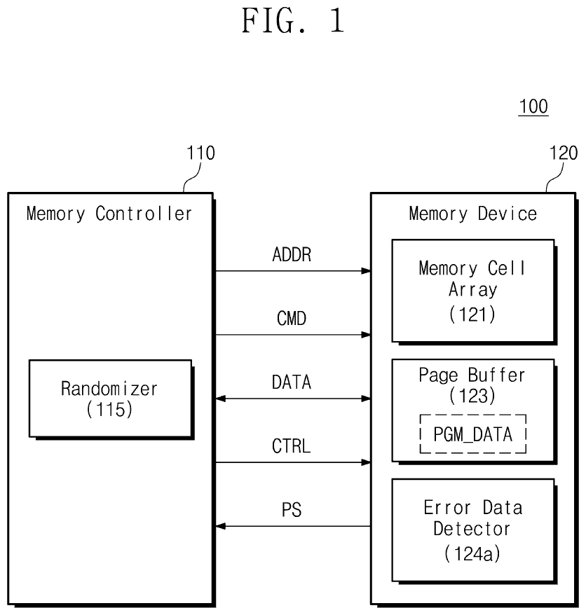

FIG. 1 is a block diagram illustrating a storage device according to an embodiment of the present disclosure. Referring to FIG. 1, a storage device 100 may include a memory controller 110 and a memory device 120. In an embodiment, the storage device 100 may be a high-capacity storage medium such as a solid state drive (SSD), a memory card, or a memory stick.

The memory controller 110 may control all the operations of the storage device 100. For example, based on a request from an external host (not illustrated), the storage device 100 may store data “DATA” in the memory device 120 or may read the data “DATA” stored in the memory device 120. For example, the memory controller 110 may provide an address ADDR, a command CMD, and a control signal CTRL to the memory device 120 and may exchange the data “DATA” with the memory device 120. In an embodiment, for an efficient operation of the storage device 100, the memory controller 110 may perform various maintenance operations (e.g., wear leveling, garbage collection, and bad block management).

In an embodiment, the memory controller 110 may include a randomizer 115. The randomizer 115 may generate program data PGM_DATA to be stored in the memory device 120. For example, the randomizer 115 may receive input data from the external host (not illustrated). The input data may be data requested by the external host (not illustrated) to be stored in the memory device 120. The randomizer 115 may randomize the input data to generate the program data PGM_DATA. The randomizer 115 may perform derandomizing for the data “DATA” received from the memory device 120 and may check the data stored in the memory device 120.

In an embodiment, the input data from the external host may be data corresponding to a single level cell (SLC) region of a memory cell array 121. The randomizer 115 may randomize the input data to generate the program data PGM_DATA. As the program data PGM_DATA are stored in the memory cell array 121 through the randomizing operation, the influence of memory cells on each other due to program states of the memory cells may decrease. Meanwhile, when the program data PGM_DATA are stored in memory cells through the randomizing operation, the number of memory cells having an erase state may be substantially equal to the number of memory cells having a program state.

In an embodiment, the input data from the external host may be data corresponding to a triple level cell (TLC) region of the memory cell array 121. The randomizer 115 may randomize the input data to generate the program data PGM_DATA. When the program data PGM_DATA are stored in memory cells, the number of memory cells having an erase state may be substantially equal to the number of memory cells having each of first to seventh program states.

The number of memory cells having the erase state from among memory cells in which the program data PGM_DATA generated by the randomizing operation are stored may be equal to the number of memory cells having the program state. That is, the number of bits each having a first bit value (e.g., “1”) from among bits of the program data PGM_DATA may be substantially equal to the number of bits each having a second bit value (e.g., “0”).

Meanwhile, in an embodiment, the data “DATA” may include the program data PGM_DATA. The memory controller 110 may send the program data PGM_DATA to the memory device 120 so as to be stored in the memory device 120.

Under control of the memory controller 110, the memory device 120 may store the data “DATA” (e.g., the program data PGM_DATA) or may output the stored data “DATA”. In an embodiment, the memory device 120 may include a NAND flash memory. However, the present invention is not limited thereto.

The memory device 120 may include the memory cell array 121, a page buffer 123, and an error data detector 124a. The memory cell array 121 may store the data “DATA”. The memory cell array 121 may include a plurality of memory cells.

The page buffer 123 may be connected to the memory cell array 121. The page buffer 123 may temporarily store the program data PGM_DATA sent from the memory controller 110.

The error data detector 124a may determine whether the program data PGM_DATA temporarily stored in the page buffer 123 are error data. In detail, the error data detector 124a may count the number of bits each having the first bit value (e.g., “1”) from among bits included in the program data PGM_DATA and may generate a bit count. However, the present invention is not limited thereto. For example, the error data detector 124a may count the number of bits each having the second bit value (e.g., “0”) from among the bits included in the program data PGM_DATA and may generate the bit count. The error data detector 124a may determine whether the program data PGM_DATA are error data, based on the bit count.

In an embodiment, bit values of the bits of the program data PGM_DATA may be changed (i.e., a bit flip may be caused). In this case, the bit count may be out of a reference range. This may mean that the program data PGM_DATA are error data.

For example, when an error occurs during the randomizing operation of the randomizer 115 (i.e., when the randomizer 115 fails to perform the randomizing operation normally (or successfully), the program data PGM_DATA may be error data. Also, for example, the program data PGM_DATA may become error data due to the noise generated in the memory device 120. For example, the noise may change bit values of the bits of the program data PGM_DATA. Also, for example, the program data PGM_DATA may become error data due to a communication issue which is caused on a data path between the memory controller 110 and the memory device 120 (i.e., due to a data communication issue). In detail, for example, the bit values of the bits of the program data PGM_DATA generated by the randomizer 115 may be changed on the data path. This may mean that the program data PGM_DATA are error data.

For example, the memory device 120 may receive a status check command from the memory controller 110. In this case, the memory device 120 may send a program status signal PS to the memory controller 110 in response to the status check command. The program status signal PS may include information about whether a program status of the program operation corresponds to “PASS” or “FAIL”.

In an embodiment, the memory controller 110 may receive the program status signal PS including information indicating that the program status corresponds to “PASS”. In this case, the memory controller 110 may determine that the program operation on the program data PGM_DATA is normally (or successfully) performed.

In an embodiment, the program data PGM_DATA may be error data. In this case, the memory device 120 may send, to the memory controller 110, the program status signal PS including information indicating that the program status of the program operation on the program data PGM_DATA corresponds to “FAIL”. In this case, in response to the program status signal PS, the memory controller 110 may again generate the program data corresponding to the program operation which is failed. The memory controller 110 may send the regenerated program data to the memory device 120. In an embodiment, as the memory device 120 sends the program status signal PS indicating the program fail “FAIL” to the memory controller 110, the memory device 120 may induce the reprogram operation

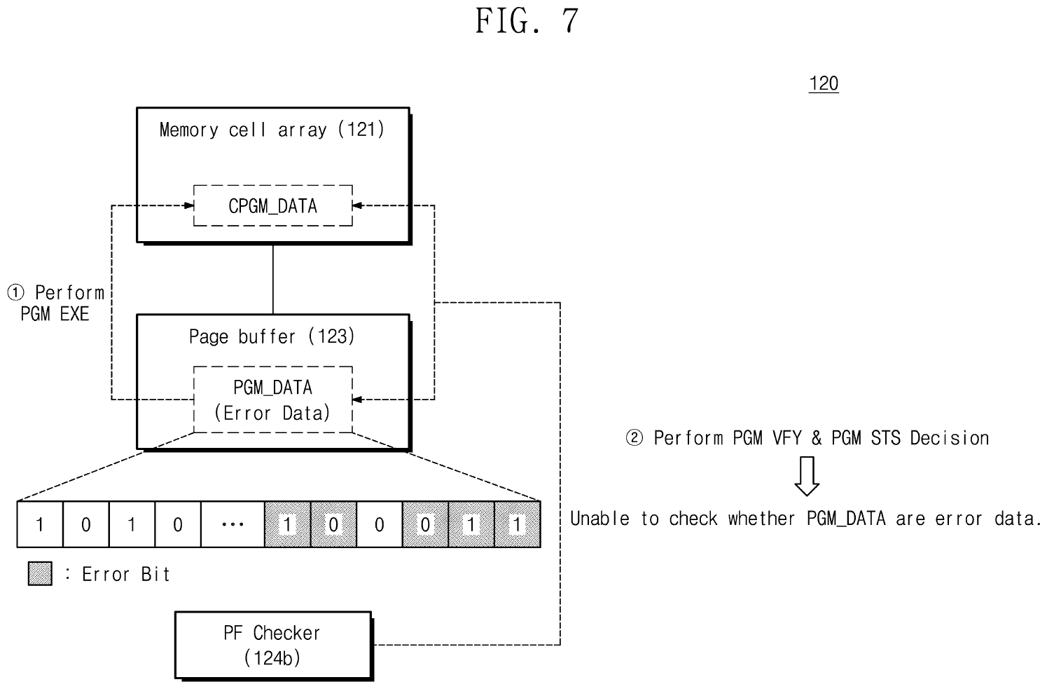

For example, the memory device 120 may not determine whether the program data PGM_DATA are error data. In this case, even though the program data PGM_DATA are error data, the memory device 120 may send the program status signal PS indicating the program pass “PASS” to the memory controller 110. The memory controller 110 may determine that the program operation on the program data PGM_DATA is normally performed even though error data are stored in the memory cell array 121. Accordingly, the data loss associated with the input data which are input from the external host and correspond to the program data PGM_DATA may occur. The occurrence of the data loss will be described in detail with reference to FIG. 7.

According to an embodiment of the present disclosure, the memory device 120 may determine whether the program data PGM_DATA temporarily stored in the page buffer 123 are error data. When the program data PGM_DATA are error data, the memory device 120 may induce the reprogram operation by sending the program status signal PS indicating the program fail “FAIL” to the memory controller 110. Accordingly, the memory device 120 may prevent the data loss. Accordingly, according to the present disclosure, a memory device with improved performance, an operating method of the memory device, and a storage device including the memory device may be provided.

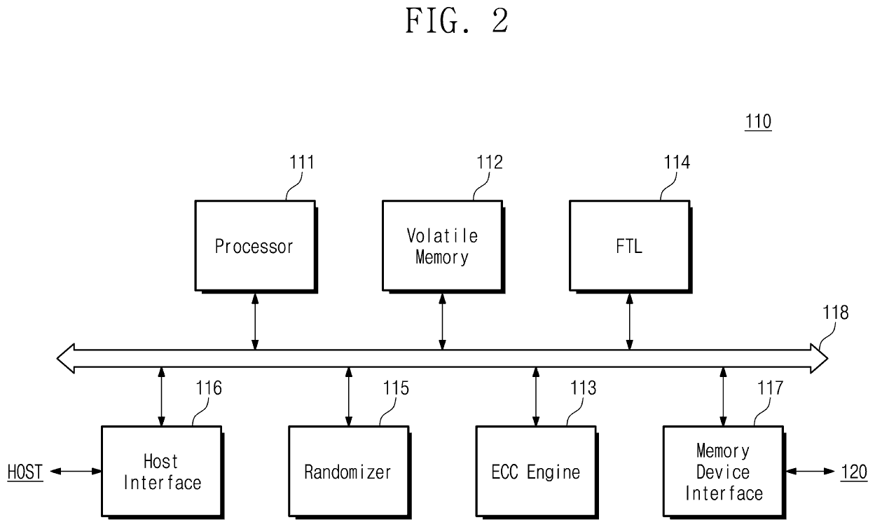

FIG. 2 is a block diagram illustrating the memory controller 110 of FIG. 1 according to example embodiments. Referring to FIG. 2, the memory controller 110 may include a processor 111, a volatile memory device 112, an ECC engine 113, a flash translation layer (FTL) 114, the randomizer 115, a host interface 116, and a memory device interface 117.

The processor 111, the volatile memory device 112, the ECC engine 113, the flash translation layer 114, the randomizer 115, the host interface 116, and the memory device interface 117 may communicate with each other through a system bus 118.

The processor 111 may control all the operations of the memory controller 110.

The volatile memory device 112 may be used as a main memory, a buffer memory, or a cache memory of the memory controller 110. The volatile memory device 112 may include information for managing a memory space of the memory device 120.

The ECC engine 113 may detect and correct an error of data obtained from the memory device 120. For example, the ECC engine 113 may have an error correction capability of a given level. The ECC engine 113 may process data whose error level (e.g., the number of flipped bits) exceeds the error correction capability, as uncorrectable error correction code (UECC) data.

The FTL 114 may translate a logical address received from an external device, for example, an external host “HOST” into a physical address used in the memory device 120. Also, the FTL 114 may perform garbage collection, read reclaim, etc. for the memory device 120.

The randomizer 115 may generate the program data PGM_DATA as described with reference to FIG. 1. In detail, the randomizer 115 may randomize the data input from the external host “HOST” to generate the program data PGM_DATA. For example, the randomizer 115 may perform the randomizing operation in units of word line. For example, the randomizer 115 may perform the randomizing operation such that the number of memory cells having the erase state or each of the program states (e.g., the first to seventh program states) from among memory cells connected to one word line is maintained to be substantially equal.

The memory controller 110 may communicate with the host “HOST” through the host interface 116. In some embodiments, the host interface 116 may be implemented based on at least one of various interfaces such as a serial ATA (SATA) interface, a peripheral component interconnect express (PCIe) interface, a serial attached SCSI (SAS), a nonvolatile memory express (NVMe) interface, a universal flash storage (UFS) interface, and a compute express link (CXL) interface.

The memory controller 110 may communicate with the memory device 120 through the volatile memory interface 117. For example, the volatile memory interface 117 may be implemented based on the NAND interface.

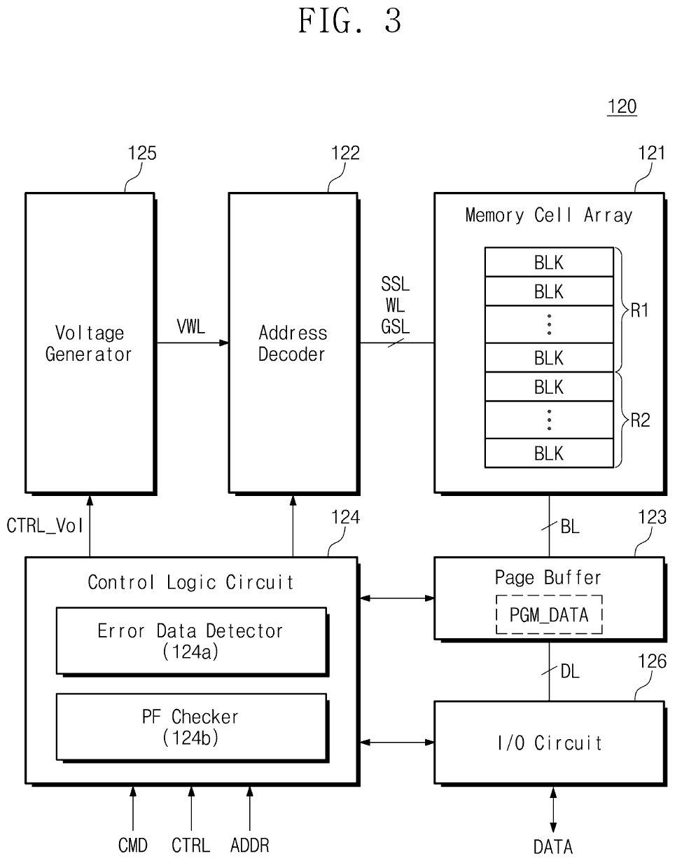

FIG. 3 is a block diagram illustrating a memory device of FIG. 1 according to example embodiments. Referring to FIGS. 1 and 3, the memory device 120 may include the memory cell array 121, an address decoder 122, the page buffer 123, a control logic circuit 124, a voltage generator 125, and an input/output circuit 126.

The memory cell array 121 may include a plurality of memory cells. Also, the memory cell array 121 may include a plurality of memory blocks BLK. Each of the plurality of memory blocks BLK may be connected to the address decoder 122 through word lines WL, string selection lines SSL, and ground selection lines GSL. The memory cell array 121 may include a first region R1 and a second region R2. Each of the first region R1 and the second region R2 may include at least one memory block BLK. In an embodiment, the first region R1 may be a single level cell (SLC) region. That is, each of the memory cells included in the first region R1 may include one bit. In an embodiment, the second region R2 may be a triple level cell (TLC) region. That is, each of the memory cells included in the second region R2 may include three bits. However, the present invention is not limited thereto. For example, the memory cell array 121 may include a multi-level cell (MLC) or a quad level cell (QLC) which stores two or more bits.

The address decoder 122 may be connected to the memory cell array 121 through the string selection lines SSL, the word lines WL, and the ground selection lines GSL. The address decoder 122 may control or drive the string selection lines SSL, the word lines WL, and the ground selection lines GSL.

The page buffer 123 may be connected to the memory cell array 121 through bit lines BL. The page buffer 123 may temporarily store the program data PGM_DATA to be programmed in the memory cell array 121 or data read from the memory cell array 121.

The control logic circuit 124 may control an operation of the memory device 120 in response to the command CMD, the control signal CTRL, and the address ADDR from the memory controller 110. For example, the control logic circuit 124 may control the address decoder 122, the page buffer 123, the voltage generator 125, and the input/output circuit 126 in response to the command CMD such that an operation (e.g., a program operation, a read operation, or an erase operation) corresponding to the command CMD is performed. The control logic circuit 124 may provide a row address to the address decoder 122, may provide a column address to the page buffer 123, and may provide a voltage control signal CTRL_Vol to the voltage generator 125.

The control logic circuit 124 may include the error data detector 124a and a pass/fail checker 124b. The error data detector 124a may generate a bit count and may determine whether the program data PGM_DATA are error data, based on the bit count. The pass/fail checker 124b may determine whether a program status of the program operation on the program data PGM_DATA corresponds to “PASS” or “FAIL”.

When the program status corresponds to “PASS”, the pass/fail checker 124b may send the program status signal PS (refer to FIG. 1) indicating the program pass “PASS” to the memory controller 110 through the input/output circuit 126. When the program status corresponds to the program fail “FAIL”, the pass/fail checker 124b may send the program status signal PS (refer to FIG. 1) indicating the program fail “FAIL” to the memory controller 110 through the input/output circuit 126.

In an embodiment, the pass/fail checker 124b may determine that the program operation is not normally performed, based on an execution result of a verify (or program verify) step included in the program operation. In this case, the pass/fail checker 124b may determine that the program status corresponds to “FAIL”.

In an embodiment, when the program data PGM_DATA are error data, the pass/fail checker 124b may determine that the program status associated with the program data PGM_DATA corresponds to “FAIL”.

The voltage generator 125 may generate various kinds of voltages for performing the write, read, and erase operations on the memory cell array 121, based on the voltage control signal CTRL_vol. In detail, the voltage generator 125 may be configured to generate a word line voltage VWL, for example, a plurality of program voltages, a plurality of program verify voltages, a plurality of pass voltages, a plurality of read voltages, and an erase voltage, etc.

The input/output circuit 126 may be connected to the page buffer 123 through data lines DL and may exchange the data “DATA” with the input/output circuit 126 through the data lines DL. Under control of the control logic circuit 124, the input/output circuit 126 may send the data “DATA” to the memory controller 110 or may receive the data “DATA” from the memory controller 110. As described above, the input/output circuit 126 may send the program status signal PS (refer to FIG. 1) sent from the pass/fail checker 124b to the memory controller 110.

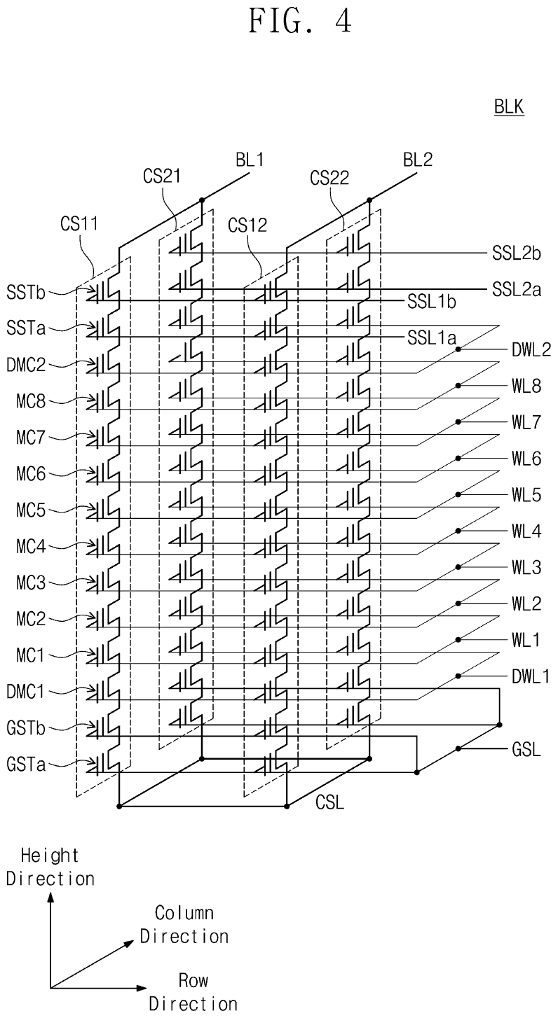

FIG. 4 is a circuit diagram illustrating a memory block of FIG. 3 according to example embodiments. One memory block BLK will be described with reference to FIG. 4, but the present invention is not limited thereto. The plurality of memory blocks BLK included in the memory cell array 121 of FIG. 3 may have a structure which is similar to or the same as that of the memory block BLK of FIG. 4. Referring to FIGS. 3 and 4, the memory block BLK may include a plurality of cell strings CS11, CS12, CS21, and CS22. The plurality of cell strings CS11, CS12, CS21, and CS22 may be arranged in a row direction and a column direction.

Cell strings located at the same column from among the plurality of cell strings CS11, CS12, CS21, and CS22 may be connected to the same bit line. For example, the cell strings CS11 and CS21 may be connected to a first bit line BL1, and the cell strings CS12 and CS22 may be connected to a second bit line BL2. Each of the plurality of cell strings CS11, CS12, CS21, and CS22 includes a plurality of cell transistors. Each of the plurality of cell transistors may be a charge trap flash (CTF) memory cell transistor, but the present invention is not limited thereto. The plurality of cell transistors may be stacked on a plane (e.g., a semiconductor substrate (not illustrated)) defined by the row direction and the column direction.

The plurality of cell transistors may be connected in series between the corresponding bit line (e.g., BL1 or BL2) and a common source line CSL. For example, the plurality of cell transistors may include string selection transistors SSTa and SSTb, dummy memory cells DMC1 and DMC2, memory cells MC1 to MC8, and ground selection transistors GSTa and GSTb. The serially-connected string selection transistors SSTa and SSTb may be provided or connected between the serially-connected memory cells MC1 to MC8 and the corresponding bit line (e.g., BL1 and BL2). The serially-connected ground selection transistors GSTa and GSTb may be provided or connected between the serially-connected memory cells MC1 to MC8 and the common source line CSL.

In each of the plurality of cell strings CS11, CS12, CS21, and CS22, memory cells located at the same height from among the memory cells MC1 to MC8 may share the same word line.

Dummy memory cells located at the same height from among the dummy memory cells DMC1 and DMC2 of the plurality of cell strings CS11, CS12, CS21, and CS22 may share the same dummy word line.

String selection transistors located at the same height and the same row from among the string selection transistors SSTa and SSTb of the plurality of cell strings CS11, CS12, CS21, and CS22 may share the same string selection line.

Although not illustrated, string selection transistors located at the same row from among the string selection transistors SSTa and SSTb of the plurality of cell strings CS11, CS12, CS21, and CS22 may share the same string selection line.

Ground selection transistors located at the same height and the same row from among the ground selection transistors GSTa and GSTb of the plurality of cell strings CS11, CS12, CS21, and CS22 may be connected to the same ground selection line.

The ground selection transistors GSTa and GSTb of the plurality of cell strings CS11, CS12, CS21, and CS22 may share the same ground selection line. Alternatively, ground selection transistors located at the same height from among the ground selection transistors GSTa and GSTb of the plurality of cell strings CS11, CS12, CS21, and CS22 may share the same ground selection line. Alternatively, ground selection transistors located at the same row from among the ground selection transistors GSTa and GSTb of the plurality of cell strings CS11, CS12, CS21, and CS22 may share the same ground selection line.

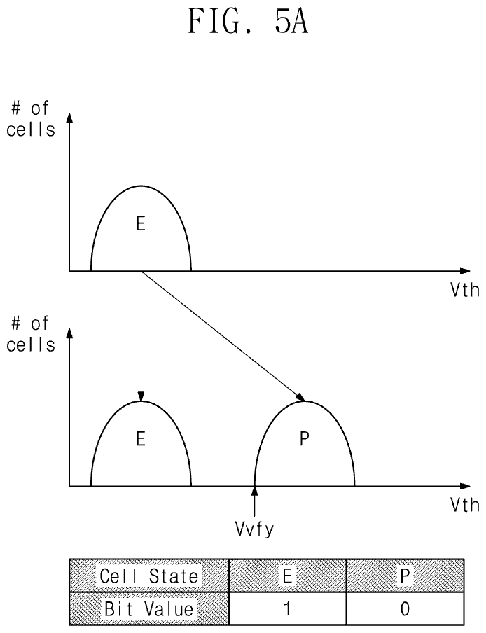

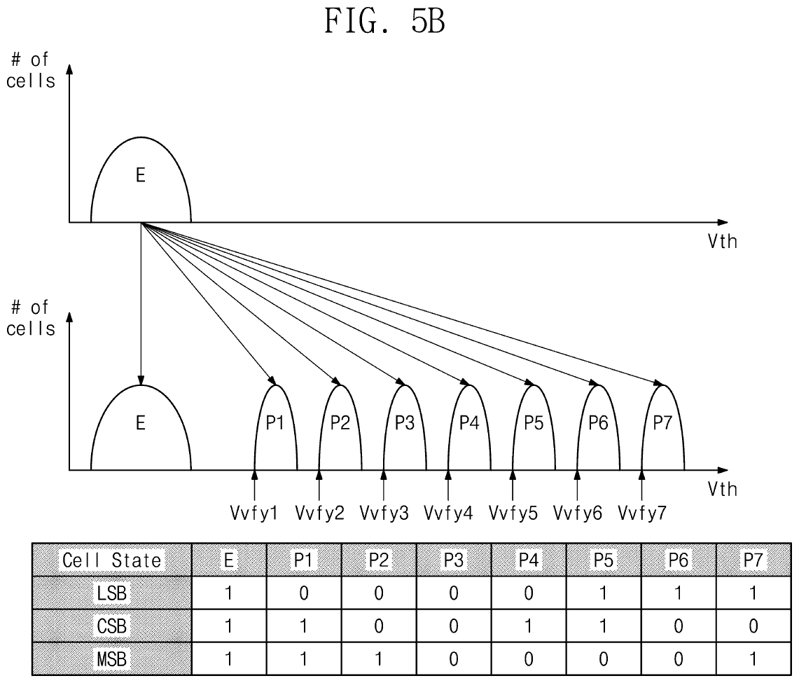

FIGS. 5A and 5B are diagrams illustrating threshold voltage distributions of memory cells illustrated in FIG. 4 according to example embodiments. In detail, FIG. 5A is a diagram illustrating threshold voltage distributions which memory cells included in the SLC region (e.g., the first region R1) of the memory cell array 121 are capable of having. FIG. 5B is a diagram illustrating threshold voltage distributions which memory cells included in the TLC region (e.g., the second region R2) of the memory cell array 121 are capable of having. In the distribution diagrams of FIGS. 5A and 5B, the horizontal axis represents a threshold voltage of a memory cell, and the vertical axis represents the number of memory cells.

Referring to FIGS. 3, 4, 5A, and 5B, the storage device 100 may store or program data in memory cells (e.g., MC1 to MC4 of FIG. 4) by changing threshold voltages of the memory cells included in the memory cell array 121.

Referring to FIG. 5A, the storage device 100 may perform the program operation on the memory cells of the SLC region (e.g., the first region R1) based on the program data PGM_DATA such that the memory cells having an erase state “E” have the erase state “E” or a program state “P”. In an embodiment, the program operation may be performed in units of word line or page.

Referring to the table of the SLC region (e.g., the first region R1), the erase state “E” may correspond to the first bit value of “1”, and the program state “P” may correspond to the second bit value of “0”. However, the present invention is not limited thereto.

For example, the storage device 100 may perform the program operation such that a specific memory cell has the program state “P”. The program operation may include a program execution step and a verify step (or program verify step). At the program execution step, the storage device 100 may perform an operation of applying a program voltage to a word line connected to selected memory cells to change threshold voltages of the selected memory cells. At the verify step, the storage device 100 may perform an operation of applying a verify voltage (or program verify voltage) Vvfy to a selected word line connected to a specific memory cell to verify a program state of the specific memory cell. That is, through the verify step, the storage device 100 may determine whether the program operation is normally performed.

Referring to FIG. 5B, the storage device 100 may perform the program operation on the memory cells of the TLC region (e.g., the second region R2) based on the program data PGM_DATA such that the memory cells having an erase state “E” have at least one the erase state “E” and a plurality of program states P1 to P7. In an embodiment, the program operation may be performed in units of word line or page.

For example, referring to the table of the TLC region, bits stored in the memory cell of the TLC region may include a least significant bit (LSB), a center significant bit (CSB), and a most significant bit (MSB). In other words, the program data PGM_DATA which are stored in the TLC region may include MSBs, CSBs, and LSBs.

For example, the erase state “E” may correspond to data “111”, the first program state P1 may correspond to data “011”, the second program state P2 may correspond to data “001”, the third program state P3 may correspond to data “000”, the fourth program state P4 may correspond to data “010”, the fifth program state P5 may correspond to data “110”, the sixth program state P6 may correspond to data “100”, and the seventh program state P7 may correspond to data “101”.

For example, the specific memory cell may have the first program state P1. In this case, the memory cell may store the LSB having the second bit value (e.g., “0”) and the CSB and MSB each having the first bit value (e.g., “1”).

As described above, at the program execution step of the program operation, the storage device 100 may perform the operation of applying the program voltage to the word line connected to the selected memory cells to change threshold voltages of the selected memory cells. Meanwhile, at the verify step, the storage device 100 may perform the operation of applying one or more of verify voltages Vvfy1 to Vvfy7 sequentially to the selected word line connected to the specific memory cell to verify a program state of the specific memory cell.

For example, the above-described program operation may be performed by a memory device 120 (refer to FIG. 1) under the control of a memory controller 110 (refer to FIG. 1).

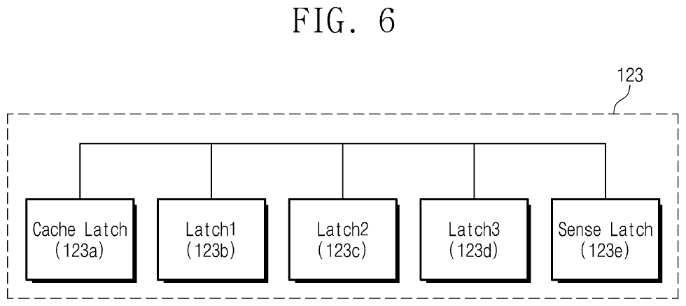

FIG. 6 is a block diagram illustrating a page buffer of FIG. 3 according to example embodiments. Referring to FIG. 6, the page buffer 123 may include a cache latch 123a and data latches (hereinafter referred to as a “first latch 123b”, a “second latch 123c”, a “third latch 123d”, and a “sense latch 123e”). The latches 123a to 123e may be electrically connected to each other. The cache latch 123a may temporarily store the program data PGM_DATA received from the memory controller 110.

For example, the program data PGM_DATA may be data to be stored in the TLC region (e.g., the second region R2 of FIG. 2). In this case, the first latch 123b may store MSB data, the second latch 123c may store CSB data, and the third latch 123d may store LSB data. The MSB data may include MSBs included in the program data PGM_DATA. The CSB data may include CSBs included in the program data PGM_DATA. The LSB data may include LSBs included in the program data PGM_DATA.

The sense latch 123e may be utilized to apply a program bit line voltage or a program-inhibition voltage to the bit lines BL during the program operation (e.g., at the program execution step). The sense latch 123e may store a sensing result of a threshold voltage of a memory cell during the program operation (e.g., at the verify step).

FIG. 7 is a diagram for describing an example of an operation of a memory device of FIG. 3 according to example embodiments. In the example of FIG. 7, it is assumed that the program data PGM_DATA are data to be stored in the SLC region (e.g., the first region R1) of the memory cell array 121. However, the present invention is not limited thereto. Referring to FIG. 7, the memory device 120 may temporarily store the program data PGM_DATA sent from the memory controller 110 in the page buffer 123. In an embodiment, the program data PGM_DATA may include a plurality of error bits.

For example, an error bit may be a bit whose value is changed (i.e., is flipped) while the program data PGM_DATA are transferred from the memory controller 110 to the memory device 120. For example, a specific factor may be a physical factor applied to a data path.

For example, an error bit may be a bit which has an unintended bit value due to an abnormal randomizing operation of the randomizer 115 (refer to FIG. 2).

Meanwhile, due to the error bits, the number of bits each having the first bit value (e.g., “1”) from among the bits included in the program data PGM_DATA may be out of the reference range. In this case, the program data PGM_DATA may be error data.

In a first operation \textcircled{1}, the memory device 120 may perform a program execution step EXE on the program data PGM_DATA. In detail, the memory device 120 may apply the program voltage to the selected word line of the memory cell array 121 to change a threshold voltage of a memory cell. Accordingly, cell program data CPGM_DATA corresponding to the program data PGM_DATA may be stored in the memory cell array 121.

In a second operation \textcircled{2}, the memory device 120 may perform a verify step VFY (or a program verify step PGM VFY) and a program status decision step PGM STS Decision. At the verify step VFY, the memory device 120 may obtain a cell count associated with whether the program operation is normally performed. At the program status decision step PGM STS Decision, the memory device 120 may determine a program status, based on the cell count.

For example, at the verify step VFY, the pass/fail checker 124b may perform a verify read operation. The verify read operation may include a first verify read operation and a second verify read operation.

During the first verify read operation, the pass/fail checker 124b may apply the verify voltage Vvfy (refer to FIG. 5A) to a word line connected to first memory cells among memory cells where the cell program data CPGM_DATA are stored. The first memory cells may be memory cells programmed to have a state (e.g., the erase state “E” of FIG. 5A) corresponding to the first bit value (e.g., “1”) from among the memory cells where the cell program data CPGM_DATA are stored. For example, the first memory cells may be memory cells which store bits each having the first bit value (e.g., “1”) from among the bits of the program data PGM_DATA. During the first verify read operation, the pass/fail checker 124b may generate a first cell count. The first cell count may indicate the number of turned-off memory cells among the first memory cells to which the verify voltage Vvfy (refer to FIG. 5A) is applied.

During the second verify read operation, the pass/fail checker 124b may apply the verify voltage Vvfy (refer to FIG. 5A) to a word line connected to second memory cells among the memory cells where the cell program data CPGM_DATA are stored. The second memory cells may be memory cells programmed to have a state (e.g., the program state “P” of FIG. 5A) corresponding to the second bit value (e.g., “0”) from among the memory cells where the cell program data CPGM_DATA are stored. In other words, the second memory cells may be memory cells which store bits each having the second bit value (e.g., “0”) from among the bits of the program data PGM_DATA. During the second verify read operation, the pass/fail checker 124b may generate a second cell count. The second cell count may indicate the number of turned-on second memory cells among the second memory cells to which the verify voltage Vvfy (refer to FIG. 5A) is applied.

For example, at the program status decision step PGM STS Decision, the pass/fail checker 124b may determine whether each of the first cell count and the second cell count is equal to or greater than a reference count. When each of the first cell count and the second cell count is smaller than the reference count, the cell program data CPGM_DATA may be substantially the same as the program data PGM_DATA. Accordingly, when each of the first cell count and the second cell count is smaller than the reference count, the pass/fail checker 124b may determine that the program operation is normally performed. Accordingly, the pass/fail checker 124b may determine whether the program status of the program operation on the program data PGM_DATA corresponds to “PASS”.

For example, when the cell program data CPGM_DATA stored in the memory cell array 121 are substantially the same as the program data PGM_DATA, the pass/fail checker 124b may determine that the program operation on the program data PGM_DATA is normally performed.

As described above, the verify step VFY may be a step of generating a cell count based on the verify voltage Vvfy to determine whether the cell program data CPGM_DATA are the same as the program data PGM_DATA. However, the above operations for generating the cell count do not limit the present invention, and operations which are performed at the verify step VFY may be variously changed or modified.

For example, the pass/fail checker 124b may determine the program status, based only on a result of the verify step VFY (i.e., the cell count). In this case, the program data PGM_DATA may be error data. That is, the cell program data CPGM_DATA may also be error data. The pass/fail checker 124b may generate the cell count and may determine that the program data PGM_DATA are the same as the cell program data CPGM_DATA, based on the cell count. Even in the case where the program data PGM_DATA are error data, based on that the program data PGM_DATA are the same as the cell program data CPGM_DATA, the pass/fail checker 124b may determine that the program operation is normally performed. Accordingly, the pass/fail checker 124b may determine that the program state of the program data PGM_DATA corresponds to “PASS”.

In this case, after the program operation is completed, the read operation on the cell program data CPGM_DATA being error data may be performed. As described above, the error data may be data in which bit values of a plurality of bits of normal data are changed. Accordingly, the error data may be data whose error level exceeds the error correction capability of the ECC engine 113 (refer to FIG. 2). That is, the cell program data PGM_DATA may be UECC data.

In other words, the memory device 120 may not check whether the program data PGM_DATA are error data. Accordingly, the data loss may occur in association with the input data received from the external host. In this case, the input data may correspond to the program data PGM_DATA.

According to an embodiment of the present disclosure, the memory device 120 may determine whether the program data PGM_DATA are error data. When the program data PGM_DATA are error data, the memory device 120 may determine that the program status of the program operation on the program data PGM_DATA corresponds to “FAIL”, regardless of the cell count generated at the verify step VFY. For example, regardless of whether the program data PGM_DATA are normally stored in the memory cell array 121, the memory device 120 may determine that the program data PGM_DATA are error data. Accordingly, the memory device 120 may induce the memory controller 110 to reprogram the input data corresponding to the program data PGM_DATA. According to the above description, the occurrence of the data loss may be prevented.

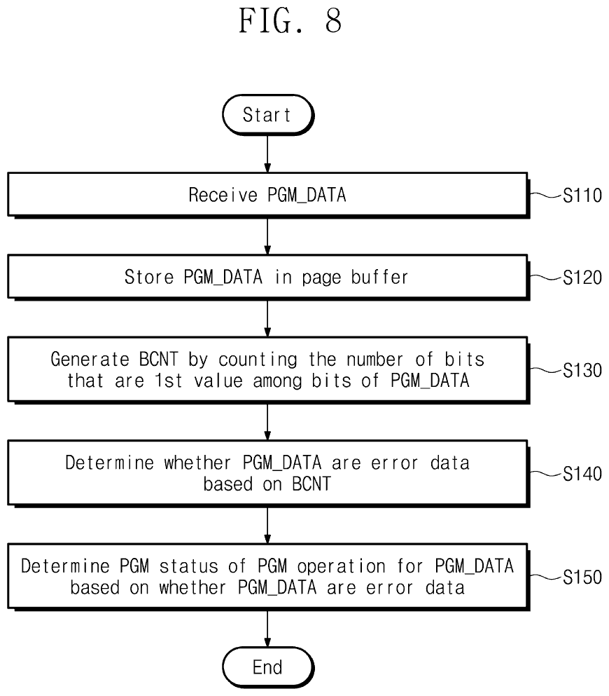

FIG. 8 is a flowchart for describing an operating method of a memory device of FIG. 3 according to example embodiments. Referring to FIG. 8, in operation S110, the memory device 120 may receive the program data PGM_DATA. In detail, the memory device 120 may receive the program data PGM_DATA from the memory controller 110.

In operation S120, the memory device 120 may temporarily store the program data PGM_DATA in the page buffer 123.

In operation S130, the memory device 120 may generate a bit count BCNT by counting bits each having the first bit value from among bits of the program data PGM_DATA. For example, the bit count BCNT may indicate the number of bits each having the first bit value (e.g., “1”) from among the bits of the program data PGM_DATA. The error data detector 124a may generate the bit count BCNT by counting the number of bits each having the first bit value (e.g., “1”) from among the bits of the program data PGM_DATA stored in the page buffer 123. However, as described above, the bit count BCNT may indicate the number of bits each having the second bit value (e.g., “0”) from among the program data PGM_DATA.

In operation S140, based on the bit count BCNT, the memory device 120 may determine whether the program data PGM_DATA are error data. In detail, based on whether the bit count BCNT belongs to the reference range, the error data detector 124a may determine whether the program data PGM_DATA are error data.

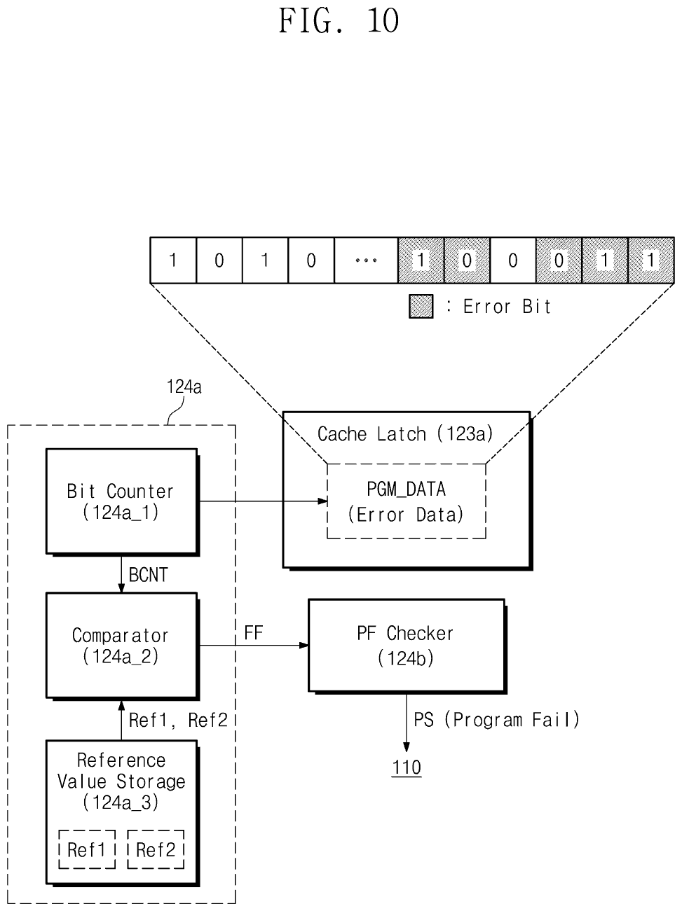

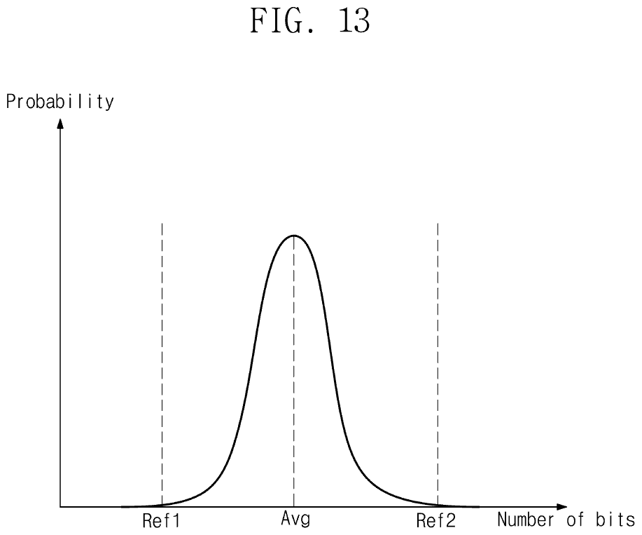

In operation S150, the memory device 120 may determine the program status of the program operation on the program data PGM_DATA, based on whether the program data PGM_DATA are error data. This will be described in detail with reference to FIGS. 10 and 13.

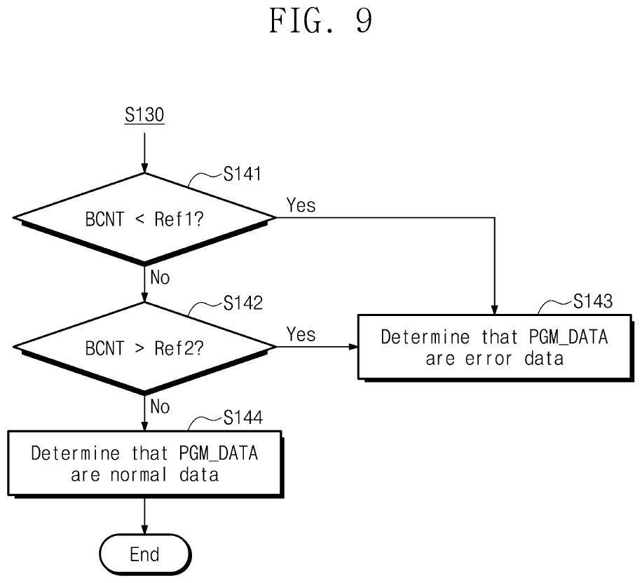

FIG. 9 is a diagram for describing an operation of determining whether program data are error data, which is described with reference to FIG. 8, in detail, according to example embodiments. Referring to FIG. 9, in operation S141, the memory device 120 may determine whether the bit count BCNT is smaller than a first reference value Ref1. When the bit count BCNT is smaller than the first reference value Ref1, the memory device 120 may perform operation S143. When the bit count BCNT is greater than the first reference value Ref1, the memory device 120 may perform operation S142.

In operation S142, the memory device 120 may determine whether the bit count BCNT is greater than a second reference value Ref2. Meanwhile, the second reference value Ref2 may be greater than the first reference value Ref1. When the bit count BCNT is smaller than the second reference value Ref2, the memory device 120 may perform operation S144. When the bit count BCNT is greater than the second reference value Ref2, the memory device 120 may perform operation S143. The first reference value and the second reference value Ref2 will be described in detail with reference to FIG. 13.

In operation S143, the memory device 120 may determine that the program data PGM_DATA are error data.

In operation S144, the memory device 120 may determine that the program data PGM_DATA are normal data.

For example, when the bit count BCNT is smaller than the first reference value Ref1 or is greater than the second reference value Ref2, the memory device 120 may determine that the bit count BCNT is out of the reference range. The memory device 120 may determine that the program data PGM_DATA are error data, based on the bit count BCNT being out of the reference range.

Meanwhile, operation S141 to operation S144 of FIG. 9 may be performed by the error data detector 124a (refer to FIG. 2).

Meanwhile, in an embodiment, the bit count BCNT may be distinguished from the cell count generated at the verify step VFY described with reference to FIG. 7. As described above, the cell count generated at the verify step VFY may be used to determine whether the cell program data CPGM_DATA stored in the memory cell array 121 are the same as the program data PGM_DATA (i.e., whether the program operation is normally performed). In contrast, the bit count BCNT may be used to determine whether the program data PGM_DATA itself are error data.

FIGS. 10 to 12 are diagrams for describing an operation of generating a bit count, which is described with reference to FIG. 8 according to example embodiments. Referring to FIGS. 3, 7, and 10, the error data detector 124a may include a bit counter 124a_1, a comparator 124a_2, and a reference value storage 124a_3.

The bit counter 124a_1 may generate the bit count BCNT, based on the program data PGM_DATA temporarily stored in the cache latch 123a of the page buffer 123. In detail, the bit counter 124a_1 may generate the bit count BCNT by counting the number of bits each having the first bit value (e.g., “1”) from among bits of the program data PGM_DATA. For example, the bit count BCNT may indicate the number of bits each having the first bit value (e.g., “1”) from among the bits of the program data PGM_DATA. For example, when the program data PGM_DATA are “10011111”, the bit count BCNT may be “6”. The bit counter 124a_1 may send the bit count BCNT to the comparator 124a_2.

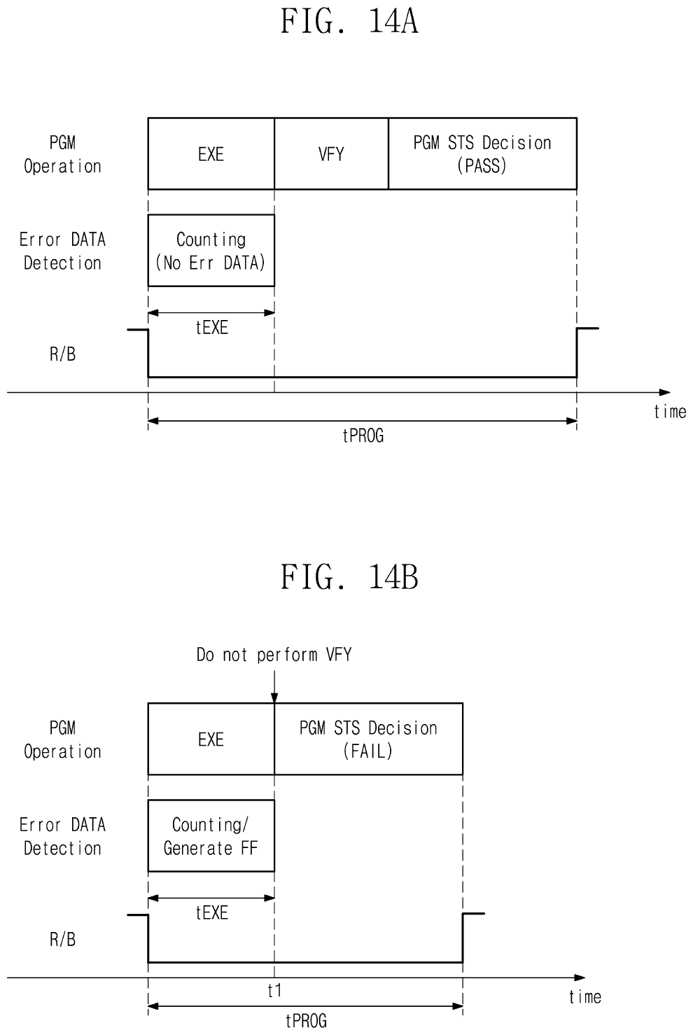

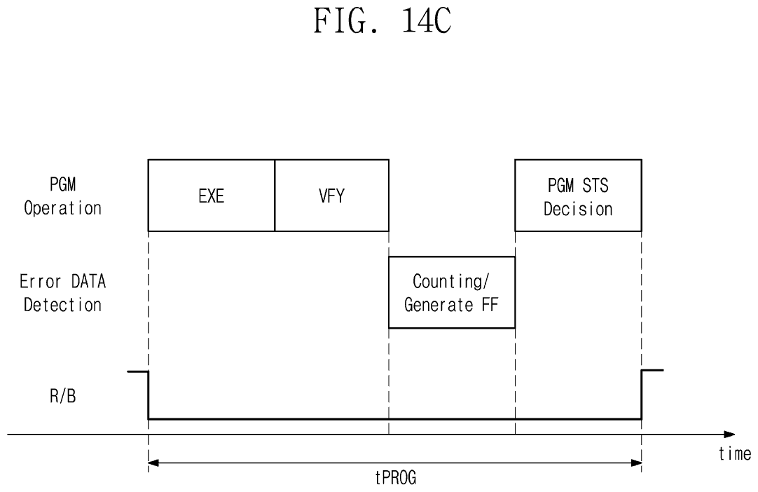

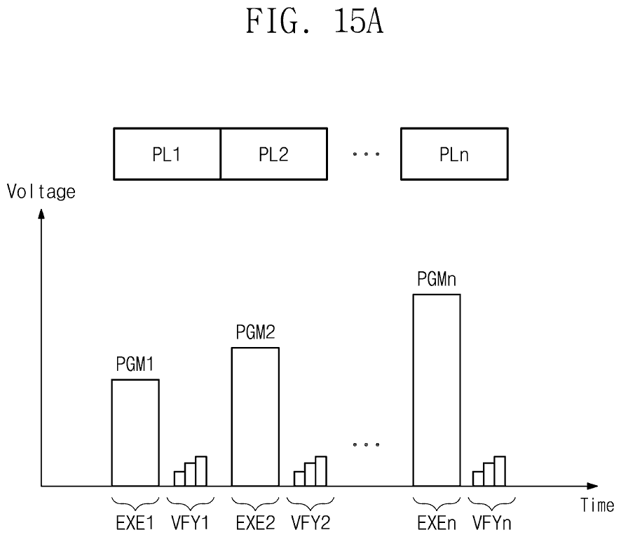

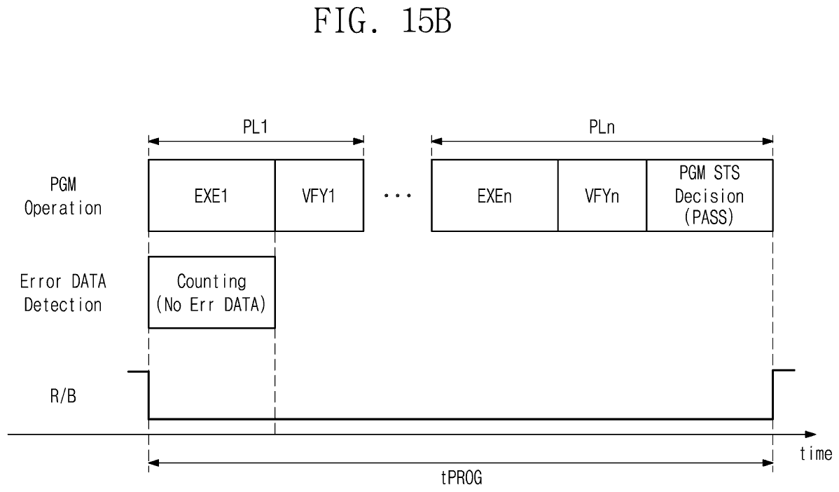

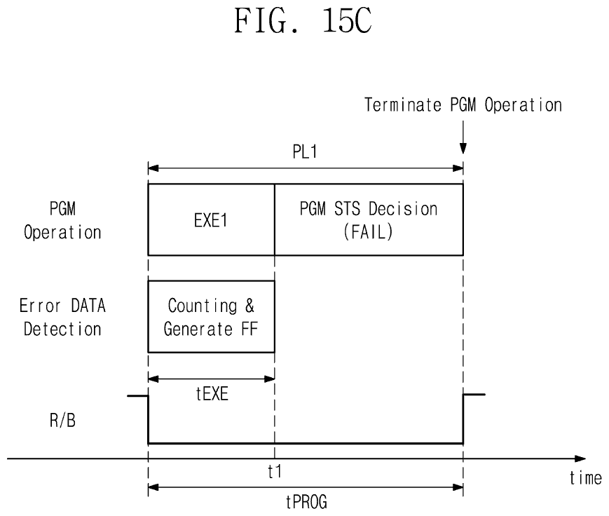

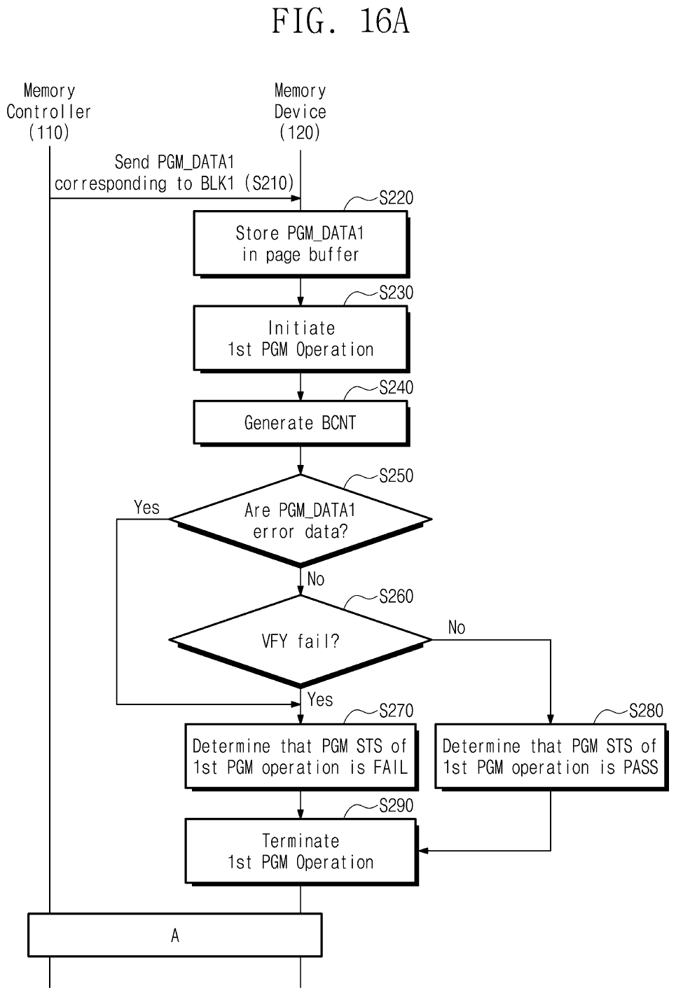

In an embodiment, when the cache latch 123a is not used for the program operation (e.g., during the execution of the program execution step), the bit counter 124a_1 may perform a counting operation for generating the bit count BCNT. The timing to perform the counting operation will be described in detail with reference to FIGS. 14A and 15C.

In an embodiment, the program data PGM_DATA may be stored in the cache latch 123a until the program execution step associated with the program data PGM_DATA is terminated.

The comparator 124a_2 may receive the bit count BCNT. The comparator 124a_2 may obtain the first reference value and the second reference value Ref2 from the reference value storage 124a_3. For example, the comparator 124a_2 may read the first reference value Ref1 and the second reference value Ref2 from the reference value storage 124a_3. The comparator 124a_2 may compare the bit count BCNT with the first and second reference values and Ref2 to determine whether the program data PGM_DATA are error data. For example, the bit count BCNT may be smaller than the first reference value or may be greater than the second reference value Ref2. In this case, the comparator 124a_2 may determine the program data PGM_DATA as error data. When the comparator 124a_2 determines the program data PGM_DATA as error data, the comparator 124a_2 may send a fail flag signal FF to the pass/fail checker 124b.

In an embodiment, regardless of whether the program data PGM_DATA are normally stored in the memory cell array 121 (refer to FIG. 3), the comparator 124a_2 may determine the program data PGM_DATA as error data, based on the bit count BCNT.

As described above, an operation in which the error data detector 124a determines whether the program data PGM_DATA are error data may be referred to as an “error data detection operation”. The error data detection operation may include an operation of generating, by the bit counter 124a_1, the bit count BCNT, an operation of comparing, by the comparator 124a_2, the bit count BCNT with the reference values and Ref2, and an operation of generating, by the comparator 124a_2, the fail flag signal FF.

The reference value storage 124a_3 may store the first reference value and the second reference value Ref2. In an embodiment, the reference value storage 124a_3 may be implemented with an electrical fuse (E-fuse) included in the control logic circuit 124 (refer to FIG. 3).

When the pass/fail checker 124b receives the fail flag signal FF, the pass/fail checker 124b may determine that the program status of the program operation on the program data PGM_DATA corresponds to “FAIL”. The pass/fail checker 124b may send the program status signal PS to the memory controller 110 through the input/output circuit 126 (refer to FIG. 3). In this case, the program status signal PS may include information indicating that the program status associated with the program data PGM_DATA corresponds to “FAIL”. For example, when the pass/fail checker 124b receives the fail flag signal FF, the pass/fail checker 124b may generate the program status signal PS indicating that the program status corresponds to “FAIL”.

In an embodiment, when the pass/fail checker 124b receives the fail flag signal FF, the pass/fail checker 124b may generate the program status signal PS indicating that the program status corresponds to “FAIL”, regardless of an execution result of the verify step included in the program operation.

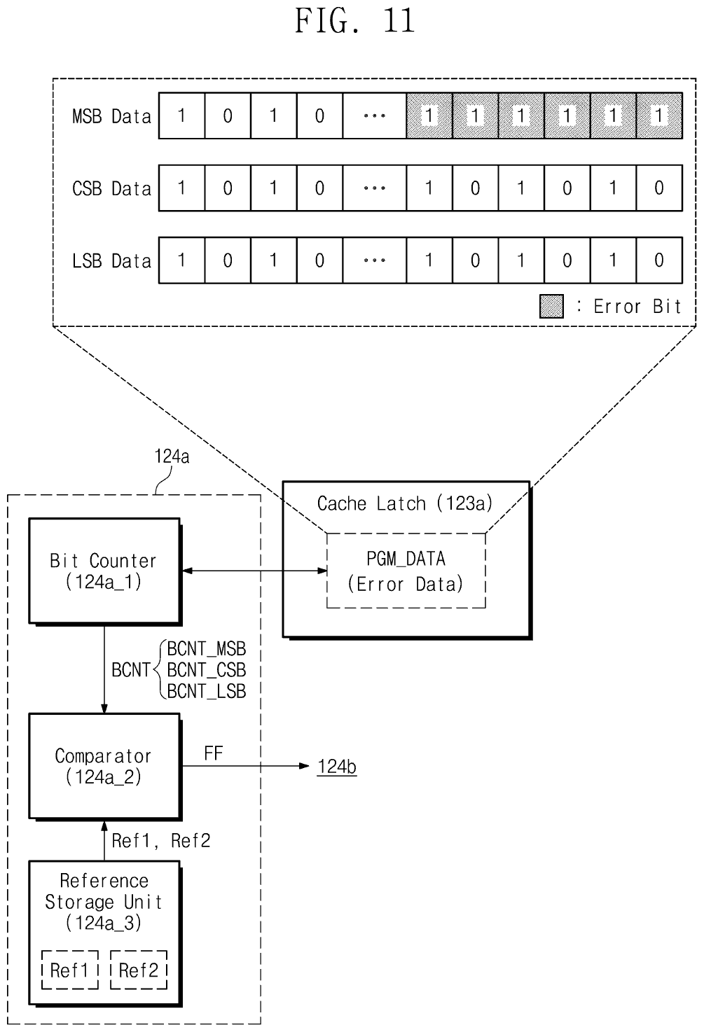

Meanwhile, referring to FIG. 11, the program data PGM_DATA may be data to be stored in the TLC region (e.g., R2 of FIG. 3). That is, the program data PGM_DATA may include MSB data, CSB data, and LSB data. In this case, the bit counter 124a_1 may generate an MSB count BCNT_MSB by counting the number of bits each having the first bit value (e.g., “1”) from among bits of the MSB data, may generate a CSB count BCNT_CSB by counting the number of bits each having the first bit value (e.g., “1”) from among bits of the CSB data, and may generate an LSB count BCNT_LSB by counting the number of bits each having the first bit value (e.g., “1”) from among bits of the LSB data. For example, the bit count BCNT may include the MSB count BCNT_MSB, the CSB count BCNT_CSB, and the LSB count BCNT_LSB.

In this case, the comparator 124a_2 may compare each of the MSB count BCNT_MSB, the CSB count BCNT_CSB, and the LSB count BCNT_LSB with the first reference value and the second reference value Ref2. The comparator 124a_2 may determine whether the program data PGM_DATA are error data, based on comparison results.

In an embodiment, when the MSB count BCNT_MSB is smaller than the first reference value or is greater than the second reference value Ref2, when the CSB count BCNT_CSB is smaller than the first reference value or is greater than the second reference value Ref2, or when the LSB count BCNT_LSB is smaller than the first reference value or is greater than the second reference value Ref2, the comparator 124a_2 may determine the program data PGM_DATA as error data. For example, when at least one of the MSB count BCNT_MSB, the CSB count BCNT_CSB, the LSB count BCNT_LSB is out of the reference range (e.g., is smaller than the first reference value or is greater than the second reference value Ref2), the comparator 124a_2 may determine the program data PGM_DATA as error data.

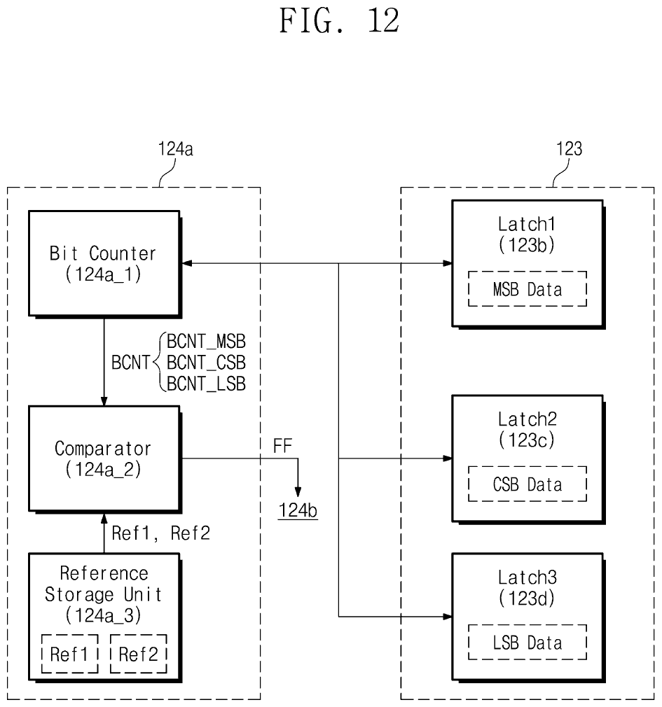

Meanwhile, referring to FIG. 12, in an embodiment, the bit counter 124a_1 may generate a bit count based on data stored in the data latches 123b to 123d. In detail, the bit counter 124a_1 may generate the MSB count BCNT_MSB by counting the number of bits each having the first bit value (e.g., “1”) from among bits of the MSB data stored in the first latch 123b. Also, the bit counter 124a_1 may generate the CSB count BCNT_CSB by counting the number of bits each having the first bit value (e.g., “1”) from among bits of the CSB data stored in the second latch 123c. Also, the bit counter 124a_1 may generate the LSB count BCNT_LSB by counting the number of bits each having the first bit value (e.g., “1”) from among bits of the LSB data stored in the third latch 123d.

In an embodiment, when the first latch 123b of the page buffer 123 is not used for the program operation, the bit counter 124a_1 may perform the counting operation for generating the MSB count BCNT_MSB. When the second latch 123c of the page buffer 123 is not used for the program operation, the bit counter 124a_1 may perform the counting operation for generating the CSB count BCNT_CSB. When the third latch 123d of the page buffer 123 is not used for the program operation, the bit counter 124a_1 may perform the counting operation for generating the LSB count BCNT_LSB.

For example, during a first time period included in the program execution step, the first latch 123b and the second latch 123c among the data latches 123b to 123d may be used, and the third latch 123d may not be used. In detail, for example, during the first time period, the sense latch 123e, the first latch 123b, and the second latch 123c may operate such that the program bit line voltage or the program-inhibition voltage is applied to the bit line BL. Meanwhile, during the first time period, the third latch 123d may not operate. In this case, during the first time period, the bit counter 124a_1 may perform the counting operation on the LSB data stored in the third latch 123d.

For example, FIGS. 10 to 12 are described based on the case where the program data PGM_DATA are data stored in the SLC region or the TLC region, but the present invention is not limited thereto. In an embodiment, the program data PGM_DATA may be data which are stored in an MLC region. Each of memory cells of the MLC region may store two bits. For example, the program data PGM_DATA may include MSB data and LSB data. In this case, the bit counter 124a_1 may generate an MSB count by counting the number of bits each having the first bit value (e.g., “1”) from among bits of the MSB data and may generate an LSB count by counting the number of bits each having the first bit value (e.g., “1”) from among bits of the LSB data. As in the above description, the comparator 124a_2 may compare each of the MSB count and the LSB count with the first reference value and the second reference value Ref2. The comparator 124a_2 may determine whether the program data PGM_DATA are error data, based on comparison results.

FIG. 13 is a graph for describing reference values of FIG. 10 according to example embodiments. In detail, FIG. 13 shows a normal distribution graph associated with the bit count BCNT of the program data PGM_DATA generated through the normal randomizing operation. In the graph of FIG. 13, the horizontal axis represents the number of bits, and the vertical axis represents a probability. Referring to FIG. 13, the probability that the bit count BCNT is smaller than the first reference value may be close to 0%. Also, the probability that the bit count BCNT is greater than the second reference value Ref2 may be close to 0%. Accordingly, when the bit count BCNT is smaller than the first reference value or is greater than the second reference value Ref2, the program data PGM_DATA may be error data.

In an embodiment, the storage device 100 (refer to FIG. 1) according to an embodiment of the present disclosure may adjust the reference values and Ref2. For example, a reference for detecting error data may be changed. In an embodiment, the storage device 100 (refer to FIG. 1) may adjust the reference values and Ref2 in response to a request from the external host.

FIGS. 14A to 14C are diagrams for describing a timing at which an error data detection operation is performed, according to example embodiments. In FIGS. 14A to 14C, the horizontal axis represents a time. Referring to FIG. 14A, during a program time tPROG, the memory device 120 may perform the program operation. The program operation may include the program execution step EXE, the verify step VFY, and the program status decision step PGM STS Decision. The program time tPROG may mean a time period where a ready/busy signal R/B output from the memory device 120 during the program operation is at a logic low level.

As described above, at the program execution step EXE, the memory device 120 may apply the program voltage to the selected word line to change program states of memory cells. Also, at the verify step VFY, the memory device 120 may apply the verify voltage to the selected word line. At the verify step VFY, the memory device 120 may measure the cell count described with reference to FIG. 7. At the program status decision step PGM STS Decision, the memory device 120 may determine the program status of the program operation, based on a result of an error data detection operation Error DATA Detection and a result of the verify step VFY.

In an embodiment, while the program execution step EXE is performed (refer to tEXE of FIG. 14A), the error data detector 124a may perform the error data detection operation Error DATA Detection. As described above, the error data detection operation Error DATA Detection may include an operation of generating, by the error data detector 124a, the bit count BCNT, an operation of comparing, by the error data detector 124a, the bit count BCNT with the reference values and Ref2, an operation of generating, by the error data detector 124a, the fail flag signal FF, and sending the fail flag signal FF to the pass/fail checker 124b.

In an embodiment, a point in time when the error data detection operation Error DATA Detection is performed may be different from a point in time when the program execution step EXE is performed. For example, the error data detection operation Error DATA Detection may be terminated at a point in time which is the same as or before an end time point of the program execution step EXE.

For example, as described above, the operation of generating the bit count BCNT through the error data detection operation Error DATA Detection may be distinguished from the operation of generating the cell count through the verify step VFY.

Returning to FIG. 14A, for example, the bit count BCNT may be within the reference range. In this case, the error data detector 124a may determine that the program data PGM_DATA are normal data. The error data detector 124a may terminate the error detection operation Error DATA Detection without generating the fail flag signal FF.

Meanwhile, at the verify step VFY, the pass/fail checker 124b may compare the program data PGM_DATA with data (e.g., the cell program data CPGM_DATA of FIG. 7) stored in the memory cell array 121. In detail, at the verify step VFY, the pass/fail checker 124b may compare the program data PGM_DATA with data stored in the sense latch 123e through the read operation for program verification. For example, when the data stored in the sense latch 123e are the same as the program data PGM_DATA, the pass/fail checker 124b may determine that the program operation is normally performed.

At the program status decision step PGM STS Decision, the pass/fail checker 124b may determine the program status. For example, the pass/fail checker 124b may not receive the fail flag signal FF. Also, through the verify step VFY, the pass/fail checker 124b may check that the program operation is normally performed. In this case, the pass/fail checker 124b may determine that the program status corresponds to “PASS”. In an embodiment, the program status decision step PGM STS Decision may be included in the verify step VFY.

In contrast, the bit count BCNT may be smaller than the first reference value Ref1 or may be greater than the second reference value Ref2. In this case, as illustrated in FIG. 14B, the error data detector 124a may generate the fail flag signal FF, and the pass/fail checker 124b may receive the fail flag signal FF.

Referring to FIG. 14B, at a first point in time t1, the program execution step EXE may be terminated. After the first point in time t1, in response to the fail flag signal FF, the pass/fail checker 124b may perform the program status decision step PGM STS Decision without performing the verify step VFY.

At the program status decision step PGM STS Decision, in response to the fail flag signal FF, the pass/fail checker 124b may determine that the program status associated with the program data PGM_DATA corresponds to “FAIL”. For example, when the program data PGM_DATA are error data, the pass/fail checker 124b may determine that the program status corresponds to “FAIL”.

Meanwhile, an example in which the error data detection operation Error DATA Detection is terminated at the end time point of the program execution step EXE is illustrated in FIGS. 14A and 14B, but the present invention is not limited thereto. According to an embodiment of the present disclosure, the error data detection operation Error DATA Detection may be performed while the program execution step EXE is performed and may be completed before the program execution step EXE is terminated.

For example, when the program data PGM_DATA are error data, to prevent the occurrence of UECC data, the memory device 120 should determine that the program status corresponds to “FAIL”, regardless of an execution result of the verify step VFY. Accordingly, when the program data PGM_DATA are error data, the memory device 120 may not need to perform the verify step VFY. According to an embodiment of the present disclosure, when the program data PGM_DATA are error data, the memory device 120 may determine that the program status corresponds to “FAIL”, without performing the verify step VFY. Accordingly, the memory device 120 may not perform the unnecessary verify step VFY.

According to an embodiment of the present disclosure, the memory device 120 may perform the error data detection operation Error DATA Detection while the program execution step EXE is performed. Accordingly, the memory device 120 may determine whether the program data PGM_DATA are error data, without an increase in the program time tPROG. Also, when the program data PGM_DATA are error data, the memory device 120 may not perform the unnecessary verify step VFY. Accordingly, the performance of the memory device 120 may be improved.

According to an embodiment of the present disclosure, unlike the above description, as illustrated in FIG. 14C, the error data detection operation Error DATA Detection may be performed after the verify step VFY is completed and before the program status decision step PGM STS Decision is performed. In this case, it may be possible to detect error data in consideration of a bit flip phenomenon which is caused during the verify step VFY. In an embodiment, in this case, the error data detector 124a may generate a bit count by counting data (e.g., the cell program data CPGM_DATA of FIG. 7) which are read from the memory cell array 121 through the verify step and are then stored in the sense latch 123e.

FIGS. 15A to 15C are diagrams for describing a timing at which an error data detection operation is performed, according to example embodiments. FIG. 15A is a timing diagram for describing the program operation of the memory device 120. In the timing diagram of FIG. 15A, the horizontal axis represents a time, and the vertical axis represents a word line voltage applied to a selected word line.

Referring to FIG. 15A, in an embodiment, the memory device 120 may perform the program operation based on an incremental step pulse programming (ISPP) manner. For example, as illustrated in FIG. 15A, the memory device 120 may perform the program operation through a plurality of program loops PL1 to PLn, n being a natural number equal to or greater than 2. Each of the plurality of program loops PL1 to PLn may include the program execution step EXE where the program voltage is applied to the selected word line and the verify step VFY of verifying program states of memory cells.

For example, the memory device 120 may perform the first program loop PL1. The first program loop PL1 may include a first program execution step EXE1 and a first verify step VFY1. The first program execution step EXE1 may refer to an operation of changing threshold voltages of memory cells by applying a first program voltage PGM1 to the selected word line. The first verify step VFY1 may refer to an operation of verifying program states of the memory cells by sequentially applying one or more of a plurality of verify voltages Vvfy1 to Vvfy7 (refer to FIG. 5B) to the selected word line.

Afterwards, the memory device 120 may perform the second program loop PL2. The second program loop PL2 may include a second program execution step EXE2 and a second verify step VFY2. The second program execution step EXE2 may refer to an operation of changing threshold voltages of the memory cells by applying a second program voltage PGM2 to the selected word line. The second verify step VFY2 may refer to an operation of verifying program states of the memory cells by sequentially applying one or more of the plurality of verify voltages Vvfy1 to Vvfy7 to the selected word line.

Afterwards, the memory device 120 may perform the n-th program loop PLn. The n-th program loop PLn may include an n-th program execution step EXEn and an n-th verify step VFYn. The n-th program execution step EXEn may refer to an operation of changing threshold voltages of the memory cells by applying an n-th program voltage PGMn to the selected word line. The n-th verify step VFYn may refer to an operation of verifying program states of the memory cells by sequentially applying one or more of the plurality of verify voltages Vvfy1 to Vvfy7 to the selected word line.

In an embodiment, as the program loop is repeatedly performed, the level of program voltage which is applied to the selected word line may increase. For example, the second program voltage PGM2 may be higher than the first program voltage PGM1 as much as a given level. The n-th program voltage PGMn may be higher than a program voltage of a previous, that is, (n−1)-th program loop as much as the given level. In each program loop, the program voltage may change as much as the given level or may change depending on states of memory cells.

Referring to FIG. 15B, during the program time tPROG, the memory device 120 may perform the program operation. While the first program execution step EXE1 of the first program loop PL1 is performed, the memory device 120 may perform the error data detection operation.

In detail, the error data detector 124a may generate the bit count BCNT, based on the program data PGM_DATA. In an embodiment, the bit count BCNT may be within the reference range. In this case, the error data detector 124a may determine that the program data PGM_DATA are normal data (i.e., no error data).

For example, in the n-th program loop PLn, the memory device 120 may perform the program status decision step PGM STS Decision. Through the n-th verify step VFYn, the memory device 120 may determine that the program operation is normally performed. Accordingly, at the program status decision step PGM STS Decision, the memory device 120 may determine that the program status corresponds to “PASS”.

For example, the bit count BCNT generated during the execution of the first program loop PL1 may be smaller than the first reference value or may be greater than the second reference value Ref2. In this case, as illustrated in FIG. 15C, the error data detector 124a may generate the fail flag signal FF.

Referring to FIG. 15C, the memory device 120 may not perform the first verify step VFY1 and the second to n-th program loops PL2 to PLn. The memory device 120 may perform the program status decision step PGM STS Decision immediately after the first program execution step EXE1 is completed. At the program status decision step PGM STS Decision, in response to that the fail flag signal FF is generated, the memory device 120 may determine that the program status corresponds to “FAIL”.

According to the present disclosure, when the program data PGM_DATA are error data, the memory device 120 may determine that the program status corresponds to “FAIL”, without performing the unnecessary program loop(s), and may then terminate the program operation. Accordingly, the performance of the memory device 120 may be improved.

An example where the error data detection operation Error DATA Detection is performed in the first program loop PL1 is illustrated in FIGS. 15B and 15C, but the present invention is not limited thereto. For example, the error data detection operation Error DATA Detection may be performed before all the program loops PL are terminated. For example, the error data detection operation Error DATA Detection may be performed at the program execution step EXE2 of the second program loop PL2.

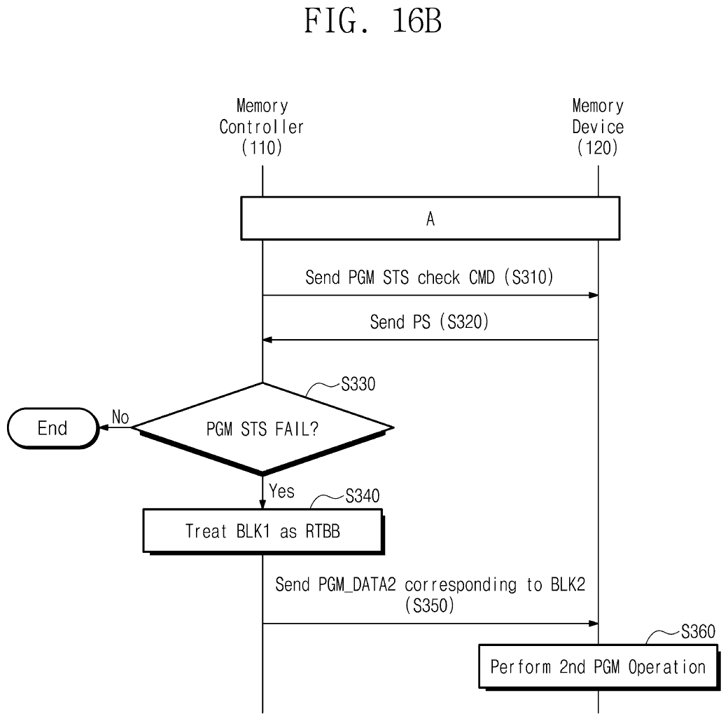

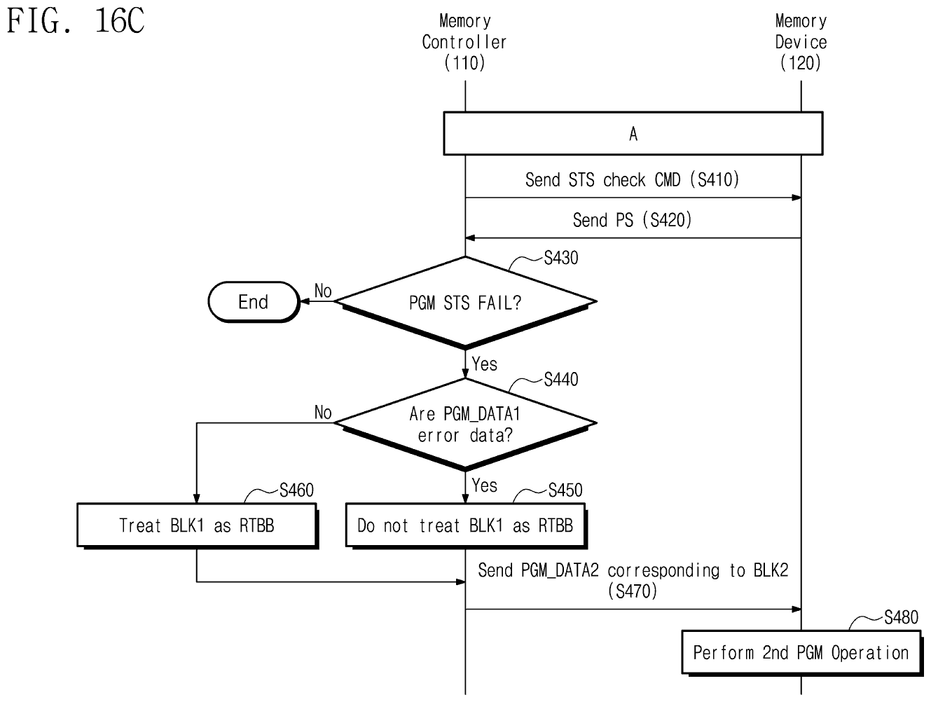

FIGS. 16A to 16C are flowcharts for describing an operating method of a storage device of FIG. 1 according to example embodiments. Referring to FIG. 16A, in operation S210, the memory controller 110 may send first program data PGM_DATA1 to the memory device 120. In this case, the first program data PGM_DATA1 may correspond to a first block BLK1 of the memory cell array 121.

In operation S220, the memory device 120 may temporarily store the first program data PGM_DATA1 in the page buffer 123.

In operation S230, the memory device 120 may initiate a first program operation.

In operation S240, the memory device 120 may generate the bit count BCNT. In detail, the error data detector 124a may generate the bit count BCNT based on the first program data PGM_DATA1 temporarily stored in the page buffer 123. The error data detector 124a may generate the bit count BCNT by counting the number of bits each having the first bit value (e.g., “1”) from among bits of the first program data PGM_DATA1.

In operation S250, the memory device 120 may determine whether the first program data PGM_DATA1 are error data. In detail, the error data detector 124a may compare the bit count BCNT with the first reference value and the second reference value Ref2 and may determine whether the first program data PGM_DATA1 are error data. For example, when the first program data PGM_DATA1 are error data, the memory device 120 may perform operation S270. When the first program data PGM_DATA1 are not error data (i.e., normal data), the memory device 120 may perform operation S260.

In operation S260, the memory device 120 may determine whether program verification corresponds to “FAIL”. For example, when an execution result of the verify step VFY indicates that a memory cell does not reach a target program state, the pass/fail checker 124b may determine that program verification is failed. For example, even though the number of program loops (e.g., “n”) reaches the maximum number of times, when a memory cell does not reach a target program state, the pass/fail checker 124b may determine that program verification is failed.

In operation S270, the memory device 120 may determine that the program status associated with the first program operation corresponds to “FAIL”.

In operation S280, the memory device 120 may determine that the program status associated with the first program operation corresponds to “PASS”.

In operation S290, the memory device 120 may terminate the first program operation.

Referring to FIG. 16B, in operation S310, the memory controller 110 may send the program status check command to the memory device 120.

In operation S320, the memory device 120 may send the program status signal PS to the memory controller 110. In detail, in an embodiment, the pass/fail checker 124b may send the program status signal PS in response to the program status check command.

In operation S330, the memory controller 110 may determine whether the program status corresponds to “FAIL”. When the program status corresponds to “FAIL”, the memory controller 110 may perform operation S340. When the program status corresponds to “PASS”, the memory controller 110 may determine that the first program operation is normally performed and may terminate the procedure.

In operation S340, the memory controller 110 may treat the first block BLK1 as a runtime bad block (RTBB). In detail, the memory controller 110 may determine that the first program operation is abnormally performed and may treat the first block BLK1 corresponding to the first program data PGM_DATA1 as a bad block.

In operation S350, the memory controller 110 may send second program data PGM_DATA2 to the memory device 120. The second program data PGM_DATA2 may correspond to the second block BLK2.

In operation S360, the memory device 120 may perform a second program operation.

Referring to FIG. 16C, in an embodiment, unlike the case of FIG. 16B, even though the program status corresponds to “FAIL”, when the first program data PGM_DATA1 are error data, the memory controller 110 may not treat the first block BLK1 as the RTBB. In FIG. 16C, operation S410 may correspond to operation S310 of FIG. 16B, operation S420 may correspond to operation S320 of FIG. 16B, operation S430 may correspond to operation S330 of FIG. 16B, operation S470 may correspond to operation S350 of FIG. 16B, and operation S480 may correspond to operation S360 of FIG. 16B.

Referring to FIG. 16C, when the program status of the program operation for the first program data PGM_DATA1 corresponds to “FAIL”, in operation S440, the memory controller 110 may determine whether the first program data PGM_DATA1 are error data. For example, the memory controller 110 may determine whether the first program data PGM_DATA1 are error data, by checking whether the fail flag signal FF is generated by the memory device 120. When the first program data PGM_DATA1 are error data, the memory controller 110 may perform operation S450. When the first program data PGM_DATA1 are not error data, the memory controller 110 may perform operation S460.

In operation S450, the memory controller 110 may not treat the first block BLK1 as the RTBB. In an embodiment, the memory controller 110 may treat all the data of the first block BLK1, which correspond to the first program data PGM_DATA1, as invalid data.

In operation S460, the memory controller 110 may treat the first block BLK1 as the RTBB. If the program status is “FAIL” and the first program data PGM_DATA1 is not error data, this may indicate a case where a program fail has occurred due to a program verification failure. In this case, the memory controller 110 may determine that the reliability of the first block BLK1 is not guaranteed (for example, the memory lifespan has been exceeded). Accordingly, the memory controller (110) may process the first block (BLK1) as RTBB.

For example, the fact that the first program data PGM_DATA1 is error data may indicate that an error occurred during data transmission from the memory controller 110 to the memory device 120. Accordingly, in this case, the first block BLK1 may not be a bad block in which the reliability of the memory block itself is not guaranteed (for example, the memory lifespan has been exceeded). Accordingly, even if an error occurred during the data transmission, if the first block BLK1 is processed as a bad block, the first block BLK1 may not be used even if the memory lifespan of the first block BLK1 has not been exceeded. According to the embodiment of FIG. 16C, when the first program data PGM_DATA1 are error data, the memory controller 110 may not treat the first block BLK1 as the RTBB. The memory controller 110 can treat data corresponding to the first program data PGM_DATA1 in the first block BLK1 as invalid data. Accordingly, the first block BLK1 can be used to store data at a later time (for example, after garbage collection is performed on the first block BLK1). Accordingly, the memory controller 110 may efficiently use the storage space of the memory device 120.

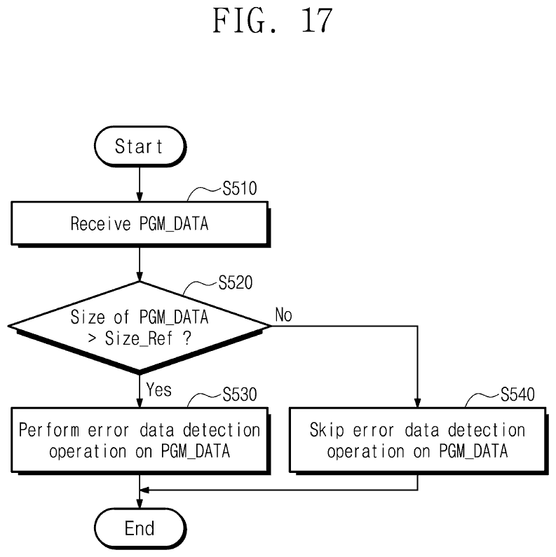

FIG. 17 is a flowchart for describing an operation of a memory device of FIG. 3 according to example embodiments. FIG. 17 will be described with reference to FIGS. 1 to 4, 5A, 5B, 6 to 13, 14A to 14C, 15A to 15C and 16A to 16C. Referring to FIG. 17, in operation S510, the memory device 120 may receive the program data PGM_DATA.

In operation S520, the memory device 120 may determine whether the size of the program data PGM_DATA is larger than the size of reference data size Size_REF. When the size of the program data PGM_DATA is larger than the size of the reference data size Size_REF, the memory device 120 may perform operation S530. When the size of the program data PGM_DATA is smaller than the size of the reference data size Size_REF, the memory device 120 may perform operation S540.

In operation S530, the memory device 120 may perform the error data detection operation. In detail, the memory device 120 may generate the bit count BCNT of the program data PGM_DATA. The memory device 120 may determine whether the program data PGM_DATA are error data, based on the bit count BCNT.

In operation S540, the memory device 120 may skip the error data detection operation. For example, the memory device 120 may not perform the error data detection operation. According to an embodiment of the present disclosure, when the size of the program data PGM_DATA is smaller than the size of the reference data size Size_REF, the memory device 120 may not perform the error data detection operation. In an embodiment, when the program operation corresponding to the program data PGM_DATA is a partial program operation, the memory device 120 may not perform the error data detection operation.

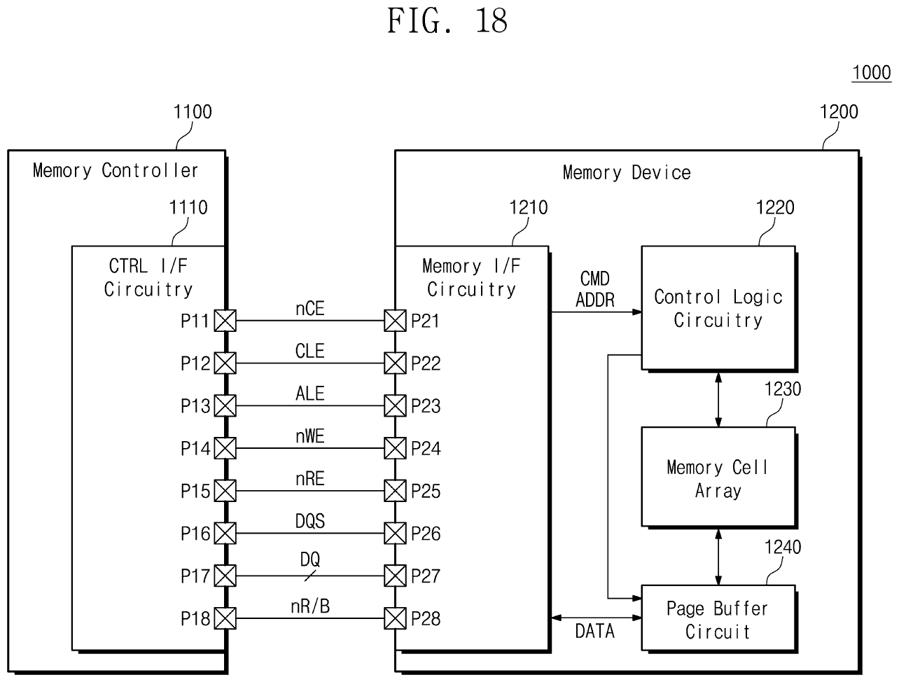

FIG. 18 is a block diagram illustrating a memory system according to an embodiment of the present disclosure. Referring to FIG. 18, a memory system 1000 may include a memory controller 1100 and a memory device 1200. In an embodiment, a communication channel between the memory controller 1100 and the memory device 1200 will be described with reference to FIG. 18, but the present invention is not limited thereto. The memory controller 1100 and any other memory devices may communicate with each other through any other channels (i.e., a plurality of channels) similar to the channel described with reference to FIG. 18.

The memory controller 1100 may correspond to the memory controller 110 of FIG. 1, and the memory device 1200 may correspond to the memory device 120 of FIG. 1.

The memory controller 1100 may include a controller interface circuitry 1110. The controller interface circuitry 1110 may include first to eighth pins P11 to P18. The memory controller 1100 may transmit various signals to the memory device 1200 through the plurality of pins P11 to P18 of the controller interface circuitry 1110. For example, the memory controller 1100 may transmit a chip enable signal nCE to the memory device 1200 through the first pin P11, may transmit a command latch enable signal CLE to the memory device 1200 through the second pin P12, may transmit an address latch enable signal ALE to the memory device 1200 through the third pin P13, may transmit a write enable signal nWE to the memory device 1200 through the fourth pin P14, may transmit a read enable signals nRE to the memory device 1200 through the fifth pin P15, may exchange a data strobe signal DQS with the memory device 1200 through the sixth pin P16, may exchange a data signal DQ with the memory device 1200 through the seventh pin P17, and may receive a ready signal (or a busy signal) nR/B from the memory device 1200 through the eighth pin P18. In an embodiment, the seventh pin P17 may include a plurality of pins depending on the way to implement.

The memory device 1200 may include a memory interface circuitry 1210, a control logic circuitry 1220, a memory cell array 1230, and a page buffer circuit 1240. The memory interface circuitry 1210 may include first to eighth pins P21 to P28. The memory interface circuitry 1210 may receive various signals from the memory controller 1100 through the first to eighth pins P21 to P28. Various signals between the memory controller 1100 and the memory device 1200 are described above, and thus, additional description will be omitted to avoid redundancy.

The memory interface circuitry 1210 may obtain the command CMD from the data signal DQ received in an enable period (e.g., at a high-level state) of the command latch enable signal CLE, based on toggle timings of the write enable signal nWE. The memory interface circuitry 1210 may obtain the address ADDR from the data signal DQ received in an enable period (e.g., at a high-level state) of the address latch enable signal ALE, based on toggle timings of the write enable signal nWE.

In an embodiment, the write enable signal nWE may maintain a static state (e.g., a high level or a low level) and may then toggle between the high level and the low level. For example, the write enable signal nWE may toggle in a period where the command CMD or the address ADDR is transmitted. In this case, the memory interface circuitry 1210 may obtain the command CMD or the address ADDR based on toggle timings of the write enable signal nWE.

In a data output operation of the memory device 1200, the memory interface circuitry 1210 may receive the toggling read enable signal nRE through the fifth pin P25 before outputting the data “DATA”. The memory interface circuitry 1210 may generate the toggling data strobe signal DQS based on toggling of the read enable signal nRE. For example, the memory interface circuitry 1210 may generate the data strobe signal DQS that starts to toggle after a given delay (e.g., tDQSRE) from a time at which the read enable signal nRE starts to toggle. The memory interface circuitry 1210 may transmit the data signal DQ including the data “DATA” in synchronization with toggle timings of the data strobe signal DQS. As such, the data “DATA” may be aligned with the toggle timings of the data strobe signal DQS and may be transmitted to the memory controller 1100.

In a data input operation of the memory device 1200, the memory interface circuitry 1210 may receive the toggling data strobe signal DQS together with the data signal DQ including the data “DATA” from the memory controller 1100. The memory interface circuitry 1210 may obtain the data “DATA” from the data signal DQ based on toggle timings of the data strobe signal DQS. For example, the memory interface circuitry 1210 may obtain the data “DATA” by sampling the data signal DQ at a rising edge and a falling edge of the data strobe signal DQS.

The memory interface circuitry 1210 may transmit a ready/busy output signal nR/B to the memory controller 1100 through the eighth pin P28. When the memory device 1200 is in a busy state (i.e., in the case where internal operations are being performed), the memory interface circuitry 1210 may transmit, to the memory controller 1100, the ready/busy output signal nR/B indicating a busy state. When the memory device 1200 is in a ready state (i.e., in the case where internal operations are not performed or are completed), the memory interface circuitry 1210 may transmit, to the memory controller 1100, the ready/busy output signal nR/B indicating a ready state.

The control logic circuitry 1220 may control various kinds of operations of the memory device 1200. The control logic circuitry 1220 may receive a command/address CMD/ADDR obtained by the memory interface circuitry 1210. The control logic circuitry 1220 may generate control signals for controlling any other components of the memory device 1200 depending on the received command/address CMD/ADDR.

The memory cell array 1230 may store the data “DATA” obtained by the memory interface circuitry 1210 under control of the control logic circuitry 1220. Under control of the control logic circuitry 1220, the memory cell array 1230 may output the stored data “DATA” to the memory interface circuitry 1210.

The memory cell array 1230 may include a plurality of memory cells. For example, the plurality of memory cells may be flash memory cells. However, the present invention is not limited thereto. For example, the memory cells may include resistive random access memory (RRAM) cells, ferroelectric random access memory (FRAM) cells, phase change random access memory (PRAM) cells, thyristor random access memory (TRAM) cells, or magnetic random access memory (MRAM) cells.

A page buffer circuit 1240 may temporarily store data to be programmed in the memory cell array 1230 under control of the control logic circuitry 1220 or may temporarily store data read from the memory cell array 1230. The page buffer circuit 1240 may exchange the data “DATA” with the memory interface circuit 1210.

In an embodiment, the memory controller 1100 may send program data (e.g., PGM_DATA of FIG. 1) to the memory device 1200 through the data signal DQ. The memory device 1200 may perform the error data detection operation to determine whether the program data (e.g., PGM_DATA of FIG. 1) are error data. In detail, the memory device 1200 may generate a bit count (e.g., BCNT of FIG. 10) by counting the number of bits each having the first bit value (e.g., “1”) from among bits of the program data (e.g., PGM_DATA of FIG. 1). Based on the bit count (e.g., BCNT of FIG. 10), the memory device 1200 may determine whether the program data (e.g., PGM_DATA of FIG. 1) are error data. In an embodiment, the memory device 1200 may perform the above error data detection operation while a program execution step (e.g., EXE of FIG. 14A) is performed within a program time (e.g., tPROG of FIG. 14A) (e.g., during tEXE of FIG. 14A). According to the above description, the memory device 1200 may prevent the data loss without an increase in the program time (e.g., tPROG of FIG. 14A), by determining whether the program data (e.g., PGM_DATA of FIG. 1) are error data. Accordingly, the memory system 1000 with improved performance may be provided.

According to example embodiments of the present disclosure, a memory device may check whether program data received from a memory controller and temporarily stored in a page buffer are error data. In this case, the memory device may prevent the loss of the program data. Accordingly, an operating method of a memory device with improved performance and a storage device including the memory device are provided.

While the present invention has been described with reference to embodiments thereof, it will be apparent to those of ordinary skill in the art that various changes and modifications may be made thereto without departing from the spirit and scope of the present invention as set forth in the following claims.

What is claimed is:

1. A memory device comprising:
a memory cell array including a plurality of memory cells;
a page buffer configured to temporarily store data, which are received from an external controller and are to be stored in the memory cell array; and
an error data detector configured to:
generate a bit count by counting the number of bits each having a first bit value from among a plurality of bits included in first data, which are temporarily stored in the page buffer and are to be stored in the memory cell array, and
determine whether the first data are error data, based on the bit count.

2. The memory device of claim 1, wherein, when the bit count is smaller than a first reference value or greater than a second reference value, the error data detector is further configured to determine that the first data are the error data, regardless of whether the first data are normally stored in the memory cell array.

3. The memory device of claim 2, wherein the error data detector includes:
a bit counter configured to generate the bit count;
a reference value storage configured to store the first reference value and the second reference value; and
a comparator configured to compare the bit count with the first reference value and the second reference value.

4. The memory device of claim 1, further comprising:
a pass/fail checker configured to determine whether a first program status of a first program operation based on the first data corresponds to a pass or a fail,
wherein, when the first data are the error data, the memory device is configured such that the pass/fail checker determines the first program status as the fail.

5. The memory device of claim 4, wherein when the first data are the error data, the memory device is configured such that the pass/fail checker determines the first program status as the fail, without performing a verify step associated with the first program operation.

6. The memory device of claim 4, wherein when the first data are the error data, the memory device is configured such that the error data detector sends a fail flag signal to the pass/fail checker, and
wherein the pass/fail checker is configured to determine the first program status as the fail in response to the fail flag signal.

7. The memory device of claim 1, wherein the plurality of memory cells include first memory cells configured to store the first data, and
wherein each of the first memory cells is a single level cell (SLC) configured to store one bit.

8. The memory device of claim 1, wherein the plurality of memory cells include second memory cells configured to store the first data,
wherein each of the second memory cells is a triple level cell (TLC) configured to store three bits,
wherein the first data includes most significant bits (MSBs), center significant bits (CSBs), and least significant bits (LSBs), and
wherein the bit count includes an MSB count indicating the number of bits each having the first bit value from among the MSBs, a CSB count indicating the number of bits each having the first bit value from among the CSBs, and an LSB count indicating the number of bits each having the first bit value from among the LSBs.

9. The memory device of claim 8, wherein, when at least one of the MSB count, the CSB count, and the LSB count is smaller than a first reference value or is greater than a second reference value, the memory device is configured such that the error data detector determines the first data as the error data.

10. The memory device of claim 1, wherein the first data are stored in the memory cell array during a program time,
wherein the program time includes:
a first time period where a program execution step for storing the first data in the memory cell array is performed; and
a second time period where a verify step for checking whether the first data are normally stored in the memory cell array is performed, and
wherein the error data detector is further configured to:
generate the bit count within the first time period, and
determine whether the first data are the error data.

11. The memory device of claim 1, wherein, when a size of the first data is smaller than a reference size, the memory device is configured such that the error data detector does not determine whether the first data are the error data, without generating the bit count.

12. An operating method of a memory device which includes a memory cell array and a page buffer, the method comprising:
receiving program data from an external controller;
storing the program data in the page buffer;
generating a bit count by counting the number of bits each having a first bit value from among a plurality of bits included in the program data temporarily stored in the page buffer; and
determining whether the program data are error data, based on the bit count.

13. The method of claim 12, wherein the determining of whether the program data are the error data includes:
when the bit count is smaller than a first reference value or when the bit count is greater than a second reference value, determining that the program data are the error data, regardless of whether the program data are normally stored in the memory cell array.

14. The method of claim 12, further comprising:
when the program data are the error data, determining a program status of a program operation for the program data as a fail.

15. The method of claim 12, wherein the program data are written in the memory cell array during a program time,
wherein the program time includes:
a first time period where a program execution step for storing the program data in the memory cell array is performed; and
a second time period where a verify step for checking whether the program data are normally stored in program memory cell array is performed, and
wherein the generating of the bit count and the determining of whether the program data are the error data are performed during the first time period.

16. The method of claim 15, further comprising:
when the program data are the error data, determining a program status of a program operation for the program data as a fail, without performing the verify step for the program data.

17. A storage device comprising:
a memory device configured to store data; and
a memory controller configured to send program data to the memory device,
wherein the memory device comprises:
a memory cell array including memory cells connected to word lines;
a row decoder configured to drive the word lines;
a page buffer configured to temporarily store the program data; and
a control logic circuit including an error data detector configured to determine whether the program data stored in the page buffer are error data,
wherein, during a program execution time, the error data detector is configured to:
generate a bit count by counting the number of bits each having a first bit value from among a plurality of bits included in the program data, and
determine whether the program data are the error data, based on the bit count, and
wherein the memory device is configured to store the program data in the memory cell array during the program execution time.

18. The storage device of claim 17, wherein, when the bit count is smaller than a first reference value or is greater than a second reference value, the memory device is configured such that the error data detector determines whether the program data are the error data.

19. The storage device of claim 17, further comprising:
a pass/fail checker configured to determine whether a first program status of a first program operation based on the program data corresponds to a pass or a fail,
wherein, when the program data are determined as the error data, the memory device is configured such that the error data detector sends a fail flag signal to the pass/fail checker.

20. The storage device of claim 19, wherein the pass/fail checker is further configured to:
determine the first program status as the fail in response to the fail flag signal, and
in response to a program status check command from the memory controller, send a program status signal which indicates that the first program status corresponds to the fail, to the memory controller.
